(19) United States
(12) Patent Application Publication
(10) Pub. No.: US 2026/0344266 A1
(43) Pub. Date: Oct. 29, 2026

(54) Display Apparatus

(71) Applicant: LG Display Co., Ltd., Seoul (KR)

(72) Inventors: Manki Ji, Daegu (KR); Sungwoo Lee, Daegu (KR); Jinwoo Park, Daegu (KR); Kyeongseob Kwon, Muju-gun (KR)

(21) Appl. No.: 19/635,321

(22) Filed: Mar. 31, 2026

(30) Foreign Application Priority Data
Apr. 28, 2025 (KR) 10-2025-0055764

(51) Int. Cl. H10K 59/80; H10K 59/40

(52) U.S. Cl. CPC H10K 59/879; H10K 59/40; H10K 59/873

(57) ABSTRACT

A display apparatus includes a display area and a non-display area. A bezel area is disposed in the non-display area in which a plurality of first structures are disposed. An encapsulation portion is disposed on the plurality of first structures. A touch sensing unit is disposed on the encapsulation portion and includes a touch sensor and a touch insulating layer. A lens is disposed on the touch sensing unit. A lens protection layer is disposed on the lens. A plurality of second structures are disposed on the touch insulating layer to be spaced apart from the lens. At least one of the plurality of second structures overlaps the plurality of first structures. A shield pattern is disposed on the touch insulating layer in the bezel area.

### CROSS-REFERENCE TO RELATED APPLICATION

This application claims priority from Republic of Korea Patent Application No. 10-2025-0055764 filed on Apr. 28, 2025, which is hereby incorporated by reference in its entirety.

### BACKGROUND

### Technical Field

The present disclosure relates to a display apparatus.

### Description of Related Art

The contents described in this section merely provides background information on the present disclosure and does not constitute the prior art.

A display apparatus is applied to an electronic device in various fields. For example, the display apparatus may be used as a means for displaying information inside a vehicle. A display apparatus disposed inside the vehicle may provide information display or alarm display for a driver. In addition, the display apparatus may provide an image for a passenger. In addition, the display apparatus may include a function of providing information to a user and allowing the user to input information through a touch function.

As a proportion of the electronic devices in a vehicle increases, the number of types of the display apparatuses disposed inside the vehicle and an area size occupied with the display apparatuses in the vehicle are also increasing. However, the information, image, or video displayed on a screen of the display apparatus may be of the type unrelated to the vehicle driving of the driver and thus may interfere with the driver when driving the vehicle. Accordingly, research on a display apparatus for a vehicle that does not interfere with the driver's driving is increasing.

When an unnecessary screen among information or images provided from a display apparatus disposed inside a vehicle is displayed on a window in a frontward and upward direction of the driver's seat, driving of the vehicle may be hindered. Accordingly, in order not to disturb the driver while driving the vehicle, a component for adjusting the viewing angle may be included in the display apparatus.

The component for adjusting the viewing angle may be susceptible to moisture penetration. For example, moisture may penetrate into the display area through the organic insulating material. When the moisture penetrates into the display area, there may be a problem in that the metal line is corroded.

In particular, when the metal line such as a touch line is damaged in a display apparatus capable of sensing a user's touch input, a defect may occur during a touch operation, which may lead to a product defect.

### SUMMARY

Accordingly, the inventors of the present disclosure have invented a display apparatus for preventing an organic insulating material from acting as a moisture flow path through various experiments.

A technical purpose to be achieved according to an embodiment of the present disclosure is to provide a display apparatus capable of improving the reliability of a product by preventing a bridge link line from being damaged due to moisture penetration or a drying etching source.

In addition, a technical purpose to be achieved according to an embodiment of the present disclosure is to provide a display apparatus capable of maintaining thickness uniformity of a protective member protecting a component for adjusting a viewing angle.

In addition, a technical purpose to be achieved according to an embodiment of the present disclosure is to provide a display apparatus capable of reducing greenhouse gas emission by reducing production energy required for production of the display apparatus.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In one embodiment, a display apparatus comprises: a substrate including a display area and a non-display area disposed outside the display area; a bezel area disposed in the non-display area in which a plurality of first structures are disposed; an encapsulation portion disposed on the plurality of first structures; a touch sensing unit disposed on the encapsulation portion and including a touch sensor and a touch insulating layer; a lens disposed on the touch sensing unit; a lens protection layer disposed on the lens; a plurality of second structures disposed on the touch insulating layer to be spaced apart from the lens, wherein at least one of the plurality of second structures overlaps the plurality of first structures; and a shield pattern disposed on the touch insulating layer in the bezel area.

In the display apparatus according to an embodiment of the present disclosure, the shield pattern is disposed on an exposed area between the adjacent lens dams, thereby preventing damage to the bridge link line, etc. This may prevent a product defect from occurring.

In addition, the display apparatus according to an embodiment of the present disclosure may quickly discharge static electricity to the outside by electrically connecting the shield pattern to a ground line. Accordingly, the static electricity may be prevented from being introduced into the display panel.

In another embodiment, a display apparatus comprises: a substrate including a display area and a non-display area disposed outside the display area; a bezel area disposed in the non-display area in which a plurality of encapsulation dams are disposed on the substrate; an encapsulation portion disposed on the plurality of first structures; a touch sensing unit disposed on the encapsulation portion and including a touch sensor and a touch insulating layer; a lens disposed on the touch sensing unit; a lens protection layer disposed on the lens; and a plurality of lens dams disposed on the touch insulating layer to be spaced apart from the lens, wherein at least one of the plurality of lens dams overlaps the plurality of encapsulation dams, and wherein a first trench is defined in the touch insulating layer in the bezel area.

The display apparatus according to an embodiment of the present disclosure may include a structure for dividing a touch insulating layer made of an organic insulating material into two portions isolated from each other in the bezel area. Accordingly, the structure may prevent the touch insulating layer from acting as the moisture penetrating path into the display area, thereby improving the reliability of the product.

In the display apparatus according to an embodiment of the present disclosure, at least a portion of the lens dam overlaps at least a portion of the encapsulation dam in the vertical direction such that the height of the lens dam may be maintained. Accordingly, the flow of the insulating material having fluidity may be controlled to prevent the insulating material from flowing to the outer area of the display apparatus. As a result, the thickness uniformity of the lens protection member may be secured to reliably protect the lens.

In addition, according to an embodiment of the present disclosure, the lens dam may be formed in the same process as the process for forming the component for adjusting the viewing angle, such that the number of the process steps may be reduced. Accordingly, there is an effect that production energy required for production of the display apparatus may be reduced and greenhouse gas emission may be reduced.

The effects of the present disclosure are not limited to the effects as mentioned above, and other effects not mentioned will be clearly understood by those skilled in the art from the following descriptions.

### BRIEF DESCRIPTION OF DRAWINGS

FIG. 1 illustrates an example in which a display apparatus according to an embodiment of the present disclosure is applied to a vehicle.

FIG. 2 is a plan view of a display apparatus according to embodiments of the present disclosure.

FIG. 3 is an enlarged view of an area I of FIG. 1.

FIG. 4 is a cross-sectional view taken along a line II-II' of FIG. 3.

FIGS. 5 and 6 are diagrams illustrating examples of a lens.

FIGS. 7 and 8 are diagrams illustrating a display panel disposed inside a vehicle.

FIGS. 9 and 10 are diagrams illustrating a display apparatus according to an embodiment of the present disclosure.

FIGS. 11-13 are respectively diagrams illustrating display apparatuses according to some further embodiment of the present disclosure.

FIG. 14 is a diagram illustrating a modified example of a shield pattern according to an embodiment of the present disclosure.

FIG. 15 is a diagram illustrating a display apparatus according to still another embodiment of the present disclosure.

FIGS. 16 and 17 are respectively diagrams illustrating display apparatuses according to some still further embodiments of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto.

The terminology used herein is directed to the purpose of describing particular embodiments only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this specification, specify the presence of the stated features, integers, operations, elements, and/or components, but do not preclude the presence or addition of one or more other features, integers, operations, elements, components, and/or portions thereof.

As used herein, the term "and/or" includes any and all combinations of one or more of associated listed items. Expression such as "at least one of" when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present "on" a second element or layer, the first element may be disposed directly on the second element or may be disposed indirectly on the second element with a third element or layer being disposed between the first and second elements or layers.

It will be understood that when an element or layer is referred to as being "connected to", or "coupled to" another element or layer, it may be directly on, connected to, or connected to the other element or layer, or one or more intervening elements or layers may be present.

In addition, it will also be understood that when an element or layer is referred to as being "between" two elements or layers, it may be the only element or layer between the two elements or layers, or one or more intervening elements or layers may also be present.

Further, as used herein, when a layer, film, region, plate, or the like is disposed "on" or "on top" of another layer, film, region, plate, or the like, the former may directly contact the latter or still another layer, film, region, plate, or the like may be disposed between the former and the latter. As used herein, when a layer, film, region, plate, or the like is directly disposed "on" or "on top" of another layer, film, region, plate, or the like, the former directly contacts the latter and still another layer, film, region, plate, or the like is not disposed between the former and the latter. Further, as used herein, when a layer, film, region, plate, or the like is disposed “under” another layer, film, region, plate, or the like, the former may directly contact the latter or still another layer, film, region, plate, or the like may be disposed between the former and the latter. As used herein, when a layer, film, region, plate, or the like is directly disposed "under" another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms "first", "second", "third", and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship with each other.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In description of flow of a signal, for example, when a signal is delivered from a node A to a node B, this may include a case where the signal is transferred from the node A to the node B via another node unless a phrase 'immediately transferred' or 'directly transferred' is used.

Hereinafter, a display apparatus according to each embodiment of the present invention will be described with reference to the accompanying drawings.

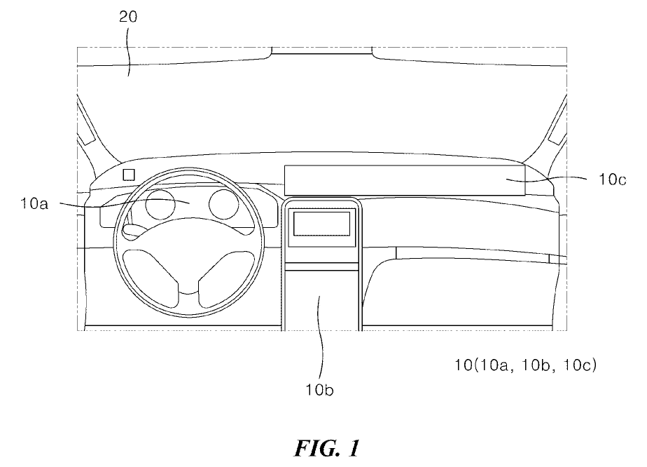

FIG. 1 illustrates an example in which a display apparatus according to an embodiment of the present disclosure is applied to a vehicle.

Referring to FIG. 1, a display apparatus including a display panel 10 according to embodiments of the present disclosure may be disposed inside a vehicle. For example, the display panel 10 may include a first display area 10a, a second display area 10b, and a third display area 10c. In an example, the first display area 10a may be disposed in front of the driver's seat, the third display area 10c may be disposed in front of the passenger's seat, and the second display area 10b may be disposed in a common space between the driver's seat and the passenger's seat.

The first display area 10a may provide information on the instrument panel indicating the driving state to the user of the driver's seat. The second display area 10b or the third display area 10c may display navigation or video according to a user's selection or a driving state of the vehicle. In an example, when the vehicle is running, the viewing angle of the second display area 10b or the third display area 10c may be controlled so as not to interfere with the driver's driving. For example, the viewing angle may be controlled so that an image provided from the second display area 10b or the third display area 10c is not reflected on the glass window in the frontward and upward direction of the driver’s seat.

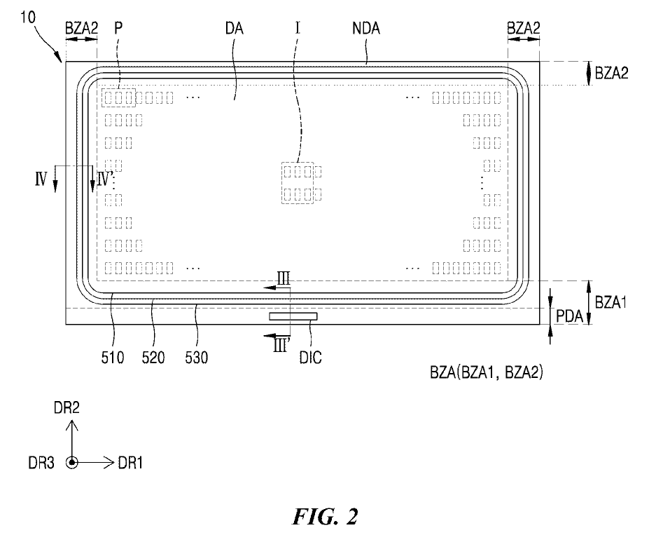

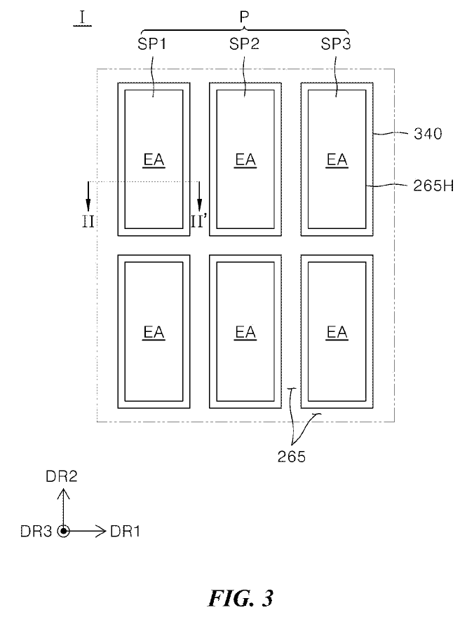

FIG. 2 is a plan view of a display apparatus according to embodiments of the present disclosure. FIG. 3 is an enlarged view of an area I of FIG. 1. FIG. 3 illustrates only a bank 265, a bank hole 265H, and a lens 340 for convenience of illustration.

Referring to FIGS. 2 and 3, the display apparatus according to an embodiment of the present disclosure may include a display panel 10 including a display area DA and a non-display area NDA positioned outside the display area DA.

The display panel 10 may include the display area DA and the non-display area NDA. The display area DA may be an area in which an image is displayed. The non-display area NDA may be an area in which no image is displayed. The non-display area NDA may be positioned in the peripheral area (or edge area) of the display panel 10. However, embodiments of the present disclosure are not limited thereto. For example, a remaining area except for a light emission area in which light is emitted to the outside in the display area DA may be referred to as the non-display area NDA. A bezel area BZA of the display apparatus may be defined by the non-display area NDA. The bezel area BZA may surround the outside of the display area DA. The bezel area BZA may include a first bezel area BZA1 and a second bezel area BZA2. The first bezel area BZA1 may be positioned at a lower portion of the display panel 10, and the second bezel area BZA2 may be positioned at an upper portion, a left portion, and a right portion of the display panel 10. The one side in the second direction DR2 of the display panel 10 in which the first bezel area BZA1 is disposed may be an area in which a pad area PDA in which a plurality of pads electrically connected to a printed circuit board or a driving circuit chip are disposed is disposed.

A plurality of pixels P may be disposed in the display area DA. Each of the plurality of pixels P may include a plurality of sub-pixels. An image may be displayed through the plurality of sub-pixels in the display area DA. The plurality of sub-pixels may be arranged in an array in the display area DA. In an example, the plurality of sub-pixels may be spaced apart from each other in the first direction DR1 and the second direction D2 intersecting the first direction DR1 of the display area DA to form a matrix arrangement. The first direction DR1 may be a longitudinal direction, an X-axis direction, or a row direction, and the second direction DR2 may be a transverse direction, a Y-axis direction, or a column direction. However, embodiment of the present disclosure are not limited thereto, and the arrangement shape, arrangement order, and arrangement direction of the sub-pixels may be variously changed.

In the present disclosure, one pixel P is configured to include a first sub-pixel SP1, a second sub-pixel SP2, and a third sub-pixel SP3. However, embodiment of the present disclosure are not limited thereto. For example, one pixel P may further include an additional sub-pixel.

The first, second and third sub-pixels SP1, SP2, and SP3 may be implemented to emit light of the same color, such as white light, or may be implemented to respectively emit light of different colors, such as red, green, and blue colors. For example, the first sub-pixel SP1 may emit the red light, the second sub-pixel SP2 may emit the green light, and the third sub-pixel SP3 may emit the blue light.

Various lines and circuits for driving the plurality of subpixels (e.g., SP1, SP2, and SP3) of the display area DA may be disposed in the non-display area NDA. For example, driving circuits including a gate driving circuit and a data driving circuit may be disposed in the non-display area NDA. Several drivers for driving the display area DA may be disposed in the non-display area NDA. For example, the driver may include a gate driver and a data driver. However, embodiments of the present disclosure are not limited thereto. A pad area PDA may be included in one edge of the non-display area NDA.

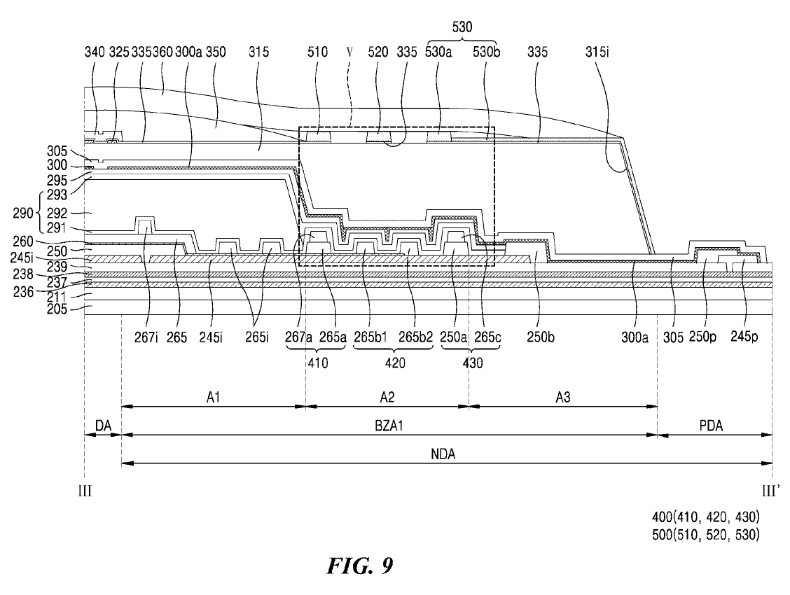

A plurality of lens dams 500 (see FIG. 9)may be disposed in the non-display area NDA so as to be spaced apart from each other. The plurality of lens dams 500 may include a first lens dam 510, a second lens dam 520, and a third lens dam 530. Each of the first, second and third lens dams 510, 520, and 530 may extend along the shape of the display area DA so as to surround the outside of the display area DA. Each of the first, second and third lens dams 510, 520, and 530 may have a continuous line shape. For example, each of the first, second and third lens dams 510, 520, and 530 may have a closed-loop line shape. The plurality of lens dams 500 may also be referred to as the plurality of second structures.

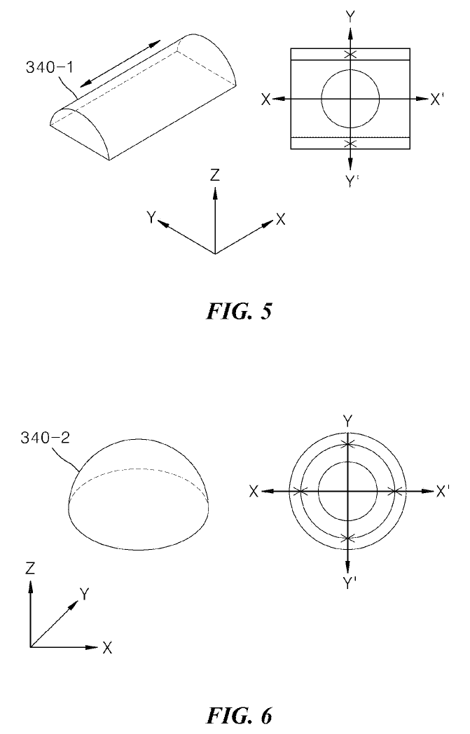

Referring to FIG. 3, the first, second and third sub-pixels SP1, SP2, and SP3 may be distinguished from each other by a bank 265. For example, the bank hole 265H as an open area of the bank 265 may constitute a boundary area between neighboring sub-pixels and may define a light-emission area EA. An area not covered with the bank 265 in each of the first, second and third sub-pixels SP1, SP2, and SP3 may be the light-emission area EA. The lens 340 as the viewing angle adjusting member may be disposed in each of the first, second and third sub-pixels SP1, SP2, and SP3 and may overlap the light-emission area EA. The lens 340 may include a hemispherical lens. However, embodiments of the present disclosure are not limited thereto. For example, the lens 340 may include a cylindrical lens. In an example, the lens 340 may function to prevent an unnecessary screen from being visible to the user. The lens 340 may be referred to as a component for adjusting a viewing angle. This will be described later with reference to FIGS. 5 and 6.

Hereinafter, an embodiment of one sub-pixel will be described.

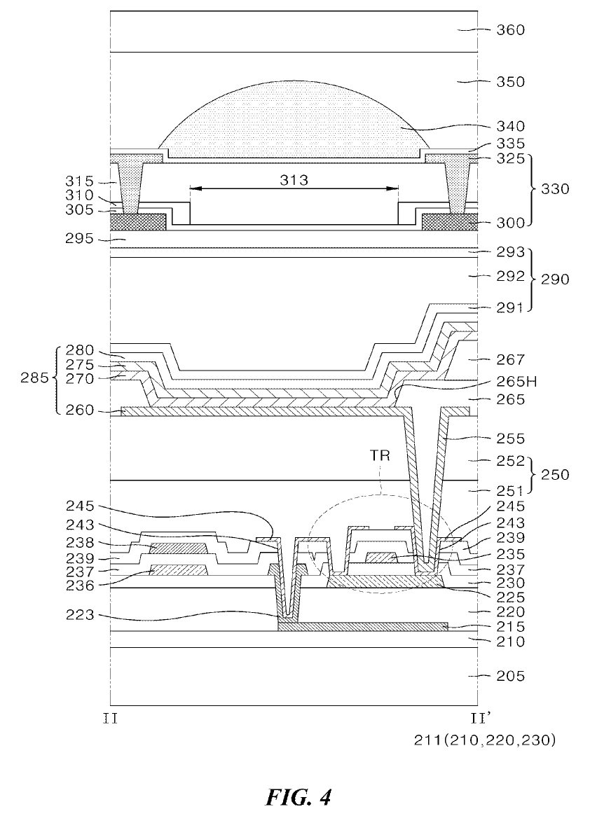

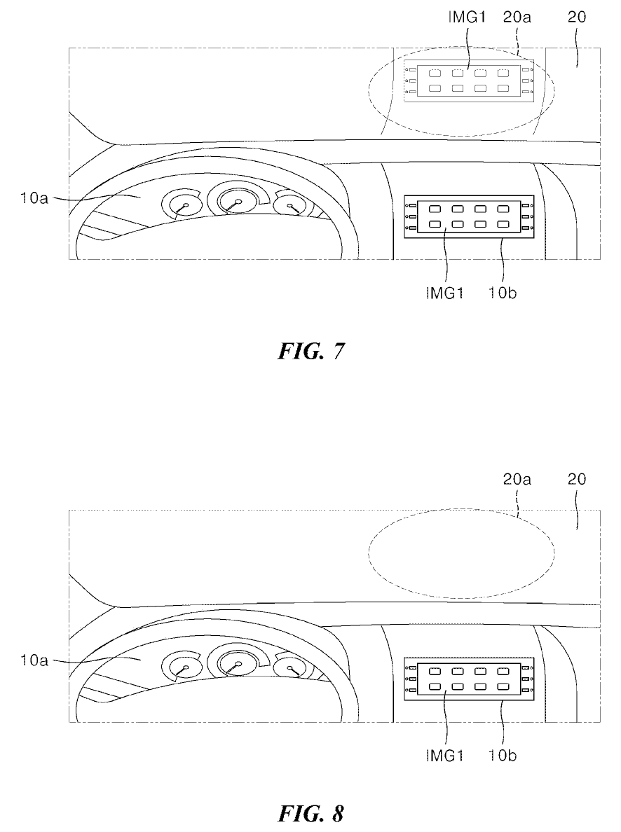

FIG. 4 is a cross-sectional view taken along a line II-II' of FIG. 3. FIGS. 5 and 6 are diagrams illustrating the lens. FIGS. 7 and 8 are diagrams illustrating a display panel disposed inside a vehicle.

Referring to FIG. 4, the display panel 10 (see FIG. 2) may include a substrate 205, a pixel driving circuit including a transistor TR, a light-emitting element 285, a touch sensing unit 330, the lens 340, a lens protection layer 350, and a polarizing layer 360.

One sub-pixel may include the light-emitting element 285 and a pixel driving circuit for applying a driving current to the light-emitting element 285. The pixel driving circuit may be disposed on the substrate 205, and the light-emitting element 285 may be disposed on the pixel driving circuit. The pixel driving circuit may include a driving transistor, one or more switching transistors, and a capacitor. In an example, the transistor TR may be a driving transistor. However, embodiments of the present disclosure are not limited thereto.

The substrate 205 may include a glass or flexible plastic film. When the substrate 205 is a plastic film, the substrate 205 may include multiple layers made of insulating materials. A first buffer layer 210 may be disposed on the substrate 205. The first buffer layer 210 may cover a surface of the substrate 205. For example, the first buffer layer 210 may entirely cover the surface of the substrate 205. The first buffer layer 210 may reduce or prevent penetration of moisture, oxygen, or impurities through the substrate 205. The first buffer layer 210 may be embodied as a single layer or a multilayer made of an inorganic insulating material such as silicon oxide (SiOx) or silicon nitride (SiNx).

A light shielding layer 215 may be disposed on the first buffer layer 210. The light shielding layer 215 may prevent external light from being incident on the transistor TR. To this end, an opaque metal material may be included in the light shielding layer 215. A second buffer layer 220 may be disposed on the light shielding layer 215. The second buffer layer 220 may be disposed across the entire surface of the substrate 205. The second buffer layer 220 may protect the transistor TR from moisture, oxygen, or impurities. The second buffer layer 220 may be embodied as a single layer or a multilayer made of an inorganic insulating material such as silicon oxide (SiOx) or silicon nitride (SiNx). However, embodiments of the present disclosure are not limited thereto.

The transistor TR may be disposed on the second buffer layer 220. The transistor TR may include a semiconductor layer 225, a gate electrode 235, and source/drain electrodes 245. The semiconductor layer 225 may include a channel area and source/drain areas. The area of the semiconductor layer 225 disposed to overlap the gate electrode 235 in the vertical direction may be a channel area. The source/drain areas may be disposed on both opposing sides of the channel area, respectively. The semiconductor layer 225 may be embodied as one of an oxide semiconductor layer, a polysilicon semiconductor layer, and a low-temperature polysilicon semiconductor layer, or a combination thereof. The semiconductor layer 225 may be disposed to overlap the light shielding layer 215 in the vertical direction. The light shielding layer 215 may prevent the external light from being incident on the semiconductor layer 225.

A gate insulating layer 230 may be disposed between the semiconductor layer 225 and the gate electrode 235. The gate insulating layer 230 may cover the semiconductor layer 225. The gate insulating layer 230 may be embodied as a single layer or a plurality of layers made of silicon oxide (SiOx) or silicon nitride (SiNx). The gate insulating layer 230 may extend into the non-display area NDA. A combination of the first buffer layer 210, the second buffer layer 220, and the gate insulating layer 230 extending into the non-display area NDA may be referred to as a first insulating structure 211.

The gate electrode 235 may be disposed on the gate insulating layer 230. The gate electrode 235 may be embodied as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the material thereof is not limited thereto.

The first intermediate electrode layer 236 may be disposed on the gate insulating layer 230. The first intermediate electrode layer 236 may be disposed in a different area from the area where the gate electrode 235 is disposed. The first intermediate electrode layer 236 may be made of the same material as that of the gate electrode 235 and be formed in the same process as the process of forming the gate electrode 235. The first intermediate electrode layer 236 may act as one of signal lines for transmitting various signals. In an example, the first intermediate electrode layer 236 may extend from the display area DA through the first bezel area BZA1 to the pad area PDA. For example, an area where the first intermediate electrode layer 236 is disposed may be an area where the driving circuit chip DIC (see FIG. 2) is disposed.

A via hole extending through the gate insulating layer 230 and the second buffer layer 220 may be disposed. The via hole may expose a portion of the surface of the light shielding layer 215. A via electrode 223 may be disposed in the via hole. The via electrode 223 may contact and be connected to the portion of the light shielding layer 215 exposed through the via hole. The via electrode 223 may extend from the inside of the via hole to a portion of an upper surface of the gate insulating layer 230.

A first interlayer insulating layer 237 may be disposed on the gate electrode 235 and the first intermediate electrode layer 236. The first interlayer insulating layer 237 may be embodied as a single layer or multiple layers made of an inorganic insulating material such as silicon oxide (SiOx) or silicon nitride (SiNx).

A second intermediate electrode layer 238 may be disposed on the first interlayer insulating layer 237. The second intermediate electrode layer 238 may be disposed in a different area from an area in which the transistor TR is disposed. For example, the second intermediate electrode layer 238 may be disposed to overlap the first intermediate electrode layer 236 in the vertical direction with the first interlayer insulating layer 237 interposed therebetween.

The second intermediate electrode layer 238 may include a metal material. For example, the second intermediate electrode layer 238 may be embodied as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. In an example, the second intermediate electrode layer 238 may act as a plurality of lines that transmit various signals from the driving circuit chip DIC (see FIG. 2) or the driver disposed on the printed circuit board to the display area DA. For example, the various signals may include a high potential voltage, a low potential voltage, a scan signal, a data signal, a touch driving signal, or the like. However, embodiments of the present disclosure are not limited thereto. In an example, the second intermediate electrode layer 238 may extend from the display area DA through the first bezel area BZA1 to the pad area PDA. For example, the area where the second intermediate electrode layer 238 is disposed may be an area where the driving circuit chip DIC (see FIG. 2) is disposed.

A second interlayer insulating layer 239 may be disposed on the second intermediate electrode layer 238 and the first interlayer insulating layer 237. The second interlayer insulating layer 239 may have a plurality of contact holes 243 formed therein. The plurality of contact holes 243 may extend through the second interlayer insulating layer 239, the first interlayer insulating layer 237, and the gate insulating layer 230 so as to contact portions of surfaces of the source/drain areas of the semiconductor layer 225, respectively. A portion of the contact hole 243 may be disposed to overlap the via electrode 223 in the vertical direction. The second interlayer insulating layer 239 may be embodied as a single layer or multiple layers made of an inorganic insulating material such as silicon oxide (SiOx) or silicon nitride (SiNx).

The source/drain electrodes 245 may be disposed on the second interlayer insulating layer 239. The source/drain electrodes 245 may extend through the second interlayer insulating layer 239, the first interlayer insulating layer 237, and the gate insulating layer 230 to be connected to the source/drain areas of the semiconductor layer 225, respectively. One of the source/drain electrodes 245 may be connected to the via electrode 223 and thus be connected to the light shielding layer 215. Each of the source/drain electrodes 245 may be embodied as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, embodiments of the present disclosure are not limited thereto. In an example, each of the source/drain electrodes 245 may have a stacked structure of a titanium layer/aluminum layer/titanium layer (Ti/Al/Ti).

A planarization layer 250 may be disposed on the source/drain electrode 245 and the second interlayer insulating layer 239. The planarization layer 250 may planarize a step due to the pixel driving circuit thereunder. The planarization layer 250 may be formed in a structure in which a plurality of planarization layers are stacked in the vertical direction. For example, in the drawing, the planarization layer 250 has a structure in which a first planarization layer 251 and a second planarization layer 252 are stacked in the vertical direction. However, embodiment of the present disclosure are not limited thereto. For example, a multilayer structure in which a third planarization layer (not shown) is further stacked on the second planarization layer 252 may be included in embodiments of the present disclosure. For example, the planarization layer 250 may include an organic insulating material such as polyimide or acrylic resin.

The light-emitting element 285 may be formed on the planarization layer 250. For example, the light-emitting element 285 may be disposed on the second planarization layer 252. The light-emitting element 285 may include a first electrode 260, a light-emitting layer 270, a second electrode 275, and a capping layer 280.

The light-emitting element 285 may be electrically connected to the pixel driving circuit via the first electrode 260. For example, a pixel contact hole 255 may be formed in the planarization layer 250. The pixel contact hole 255 may pass through the planarization layer 250, the second interlayer insulating layer 239, the first interlayer insulating layer 237, and the gate insulating layer 230. The pixel contact hole 255 may expose a portion of a surface of the other of the source/drain electrodes 245.

The first electrode 260 of the light-emitting element 285 may be electrically connected to the other of the source/drain electrodes 245 via the pixel contact hole 255. The first electrode 260 may be disposed on and contact the pixel contact hole 255 so as to be connected to the other of the source/drain electrodes 245 via the pixel contact hole 255.

The first electrode 260 may include a transparent conductive layer. The first electrode 260 may include ITO (Indium Tin Oxide) or IZO (Indium Zinc Oxide). Alternatively, the first electrode 260 may have a single-layer or multi-layer structure including a reflective metal film made of one of silver (Ag), aluminum (Al), gold (Au), nickel (Ni), and chromium (Cr) or an alloy thereof. The first electrode 260 may also be referred to as an anode electrode or a pixel electrode.

The bank 265 may be disposed on the first electrode 260. The bank 265 may be disposed to cover an edge of the first electrode 260. A portion of the bank 265 may extend onto the planarization layer 250. In an example, the bank 265 may fill a remaining portion of the pixel contact hole 255 other than the portion thereof filled with the first electrode 260. The bank 265 may have the bank hole 265H defined therein as an opening exposing a portion of the upper surface of the first electrode 260. The portion of the upper surface of the first electrode 260 not covered with the bank 265 and exposed through the bank hole 265H may be the light-emission area EA. The bank 265 may be made of an organic insulating material. The bank 265 may include, for example, photosensitive polyimide, photoacryl, or benzocyclobutene (BCB). In an example, the bank 265 may include a black material, a light blocking material, or a light absorbing material. The bank 265 may include a material that absorbs light in a specific wavelength range. The bank 265 may have a structure in which at least two color filters of different colors among a red color filter, a green color filter, and a blue color filter are stacked.

The light-emitting layer 270 may be disposed on the first electrode 260. The light-emitting layer 270 may include a hole transport layer (HTL), an organic light-emitting layer (EML), an electron transport layer (ETL), a hole blocking layer (HBL), a hole injection layer (HIL), an electron blocking layer (EBL), and an electron injection layer (EIL). The light-emitting layer 270 may have a multi-stack structure in which two or more organic light-emitting layers (EML) are stacked.

The second electrode 275 may be disposed on the light-emitting layer 270. The second electrode 275 may be formed over the entire surface of the substrate 205 so as to be commonly connected to the light-emitting layers 270 formed in all sub-pixels. Accordingly, the second electrode 275 may also be referred to as a cathode electrode or a common electrode. The second electrode 275 may include a semi-transmissive conductive material. For example, the second electrode 275 may include a metal material such as magnesium (Mg), silver (Ag), or an alloy (Ag-Mg) of silver (Ag) and magnesium (Mg). In an example, the second electrode 275 may include a transparent conductive layer made of, for example, indium-tin-oxide (ITO) or indium-zinc-oxide (IZO).

The capping layer 280 may be disposed on the second electrode 275. The capping layer 280 may correct optical characteristics by preventing light generated from the light-emitting layer 270 from being lost.

An encapsulation portion 290 may be disposed on the light-emitting element 285. The encapsulation portion 290 may protect the light-emitting element 285 from external oxygen or moisture. The encapsulation portion 290 may extend into the non-display area NDA while covering the display area DA.

The encapsulation portion 290 may include a multilayer structure in which a first encapsulation layer 291, a second encapsulation layer 292, and a third encapsulation layer 293 are stacked. The second encapsulation layer 292 may be disposed between the first encapsulation layer 291 and the third encapsulation layer 293.

The first encapsulation layer 291 may be disposed on the capping layer 280. The second encapsulation layer 292 may be disposed on the first encapsulation layer 291. The second encapsulation layer 292 may cover the first encapsulation layer 291 and may have a sufficient thickness so as to have a flat upper surface. The second encapsulation layer 292 may prevent foreign substances from invading into the light-emitting element 285. The third encapsulation layer 293 may be disposed on the second encapsulation layer 292.

An inorganic insulating material may be included in each of the first encapsulation layer 291 and the third encapsulation layer 293. For example, each of the first encapsulation layer 291 and the third encapsulation layer 293 may include at least one of silicon nitride (SiNx), silicon oxide (SiOx), and silicon oxynitride (SiON). An organic insulating material may be included in the second encapsulation layer 292. For example, the second encapsulation layer 292 may include at least one of epoxy, polyimide, polyethylene, and acrylate.

A touch sensing unit may be disposed on the encapsulation portion 290. A plurality of lenses 340 may be disposed on the touch sensing unit. The touch sensing unit may include a first touch buffer layer 295, a touch sensor 330, a second touch buffer layer 305, a light blocking pattern 310, a touch insulating layer 315, and a passivation layer 335.

The first touch buffer layer 295 may be disposed on the third encapsulation layer 293. The first touch buffer layer 295 may include an inorganic insulating material. For example, the first touch buffer layer 295 may include silicon nitride (SiNx). The first touch buffer layer 295 may relieve stress between the encapsulation portion 290 and the touch sensor 330.

The touch sensor 330 may include a plurality of touch electrodes 325 and a plurality of bridge electrodes 300. The plurality of touch electrodes 325 and the plurality of bridge electrodes 300 may be disposed in different layers. For example, the plurality of bridge electrodes 300 may be disposed on the first touch buffer layer 295. The plurality of touch electrodes 325 may be disposed on the touch insulating layer 315.

Each of the plurality of touch electrodes 325 or the plurality of bridge electrodes 300 may be embodied as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. For example, each of the plurality of touch electrodes 325 or the plurality of bridge electrodes 300 may be a stacked structure of titanium layer/aluminum layer/titanium layer (Ti/Al/Ti).

The second touch buffer layer 305 may be disposed on the plurality of bridge electrodes 300 and the first touch buffer layer 295. The touch insulating layer 315 may be disposed between the plurality of touch electrodes 325 and between adjacent ones of the plurality of bridge electrodes 300. The light blocking pattern 310 may be disposed on the second touch buffer layer 305. The plurality of touch electrodes 325 may be disposed on the touch insulating layer 315 so as to be spaced apart from each other. The bridge electrode 300 may electrically connect adjacent touch electrodes 325 to each other. To this end, each touch electrode 325 may extend through the touch insulating layer 315, the light blocking pattern 310, and the second touch buffer layer 305 so as to be electrically connected to the bridge electrode 300. Adjacent touch electrodes 325 may be electrically insulated from each other by the passivation layer 335.

An inorganic insulating material may be included in the second touch buffer layer 305 or the passivation layer 335. For example, the second touch buffer layer 305 or the passivation layer 335 may be made of an inorganic insulating material including silicon nitride (SiNx).

The touch insulating layer 315 may spread or condense the light generated from the light-emitting element 285 such that the dispersed or condensed light is directed to the lens 340. To this end, the touch insulating layer 315 may be formed to have a sufficient thickness. It may be difficult to implement the inorganic insulating material layer as the touch insulating layer 315 so as to have a thickness required by the touch insulating layer 315. Accordingly, the touch insulating layer 315 may include an organic insulating material. For example, the touch insulating layer 315 may include an organic insulating material such as acryl resin, epoxy resin, phenolic resin, polyamide resin, or polyimide resin. However, the material thereof is not limited thereto.

The light blocking pattern 310 may be disposed on the second touch buffer layer 305. The light blocking pattern 310 may prevent color mixing between light beams from adjacent light-emitting elements 285 from occurring. In addition, the light blocking pattern 310 may block light from the outside or may block light reflected from the outside. Accordingly, the luminance of the display apparatus may be further improved.

To this end, an opaque material may be included in the light blocking pattern 310. For example, the light blocking pattern 310 may include an organic insulating material including a black pigment or a black dye. In an example, the organic insulating material may include an organic material such as a benzocyclobutene resin, an epoxy resin, a polyimide resin, an acrylic resin, or a photosensitive polymer. However, embodiments of the present disclosure are not limited thereto.

A plurality of opening areas 313 may be disposed in the light blocking pattern 310. In an example, at least a portion of the opening area 313 may be disposed to overlap the light-emitting area EA of the light-emitting element 285. In an embodiment, one opening area 313 may overlap the light-emission area EA of one sub-pixel. However, embodiments of the present disclosure are not limited thereto.

The plurality of lenses 340 may be disposed on the passivation layer 335. Adjacent lenses 340 may be arranged to be spaced apart from each other by a predetermined spacing. In an example, one lens 340 may be disposed to overlap one opening area 313 defined in the light blocking pattern 310.

The lens 340 may include an organic insulating material. For example, the lens 340 may include an organic insulating material having a second density that is relatively higher than a first density of the touch insulating layer 315. The organic insulating material having the second density relatively higher than the first density of the touch insulating layer 315 may prevent the moisture from penetrating therethrough.

The lens 340 may be a hemispherical lens overlapping the opening area 313 in the vertical direction. For example, the lens 340 may have a hemispherical shape in which a convex surface protrudes toward the lens protection layer 350. A light-receiving surface of the lens 340 facing the protruding convex surface of the lens 340 and receiving the light generated from the light-emitting element 285 may be a flat surface. The light-receiving surface of the lens 340 may be in contact with the passivation layer 335.

The light generated from the light-emitting element 285 and passing through the opening area 313 may be provided to the light-receiving surface of the lens 340 and refracted by the convex surface of the lens 340 to be emitted to the outside. The light beams emitted in various directions from the light-emitting element 285 may be subjected to the change in the travel path by the lens 340 so as to be condensed in the frontward direction. Accordingly, the viewing angle of the display apparatus may be controlled.

As shown in FIGS. 5 and 6, the lens 340 may include at least one of a first lens 340-1 or a second lens 340-2. The first lens 340-1 and the second lens 340-2 may have different shapes.

For example, referring to FIG. 5, the first lens 340-1 may have a rectangular bottom surface and may have a hemispherical cylindrical shape having a hemispherical side surface in a cross-sectional view. In the bottom surface of the rectangle of the first lens 340-1, a travel path of light emitted from a width area of one sub-pixel may not be limited in a first direction X-X' (or row direction), while a travel path of the light emitted from a width area of one sub-pixel may be limited in a second direction Y-Y' (or column direction) as indicated by a mark “x”. When the display apparatus is disposed in the vehicle, the light travel along the vertical direction may be limited such that the viewing angle in the vertical direction of the display apparatus may be limited.

In addition, referring to FIG. 6, the second lens 340-2 may have a circular bottom surface and may have a hemispherical shape. Thus, in the circular bottom surface of the second lens 340-2, a travel path of the light emitted from a width area of one sub-pixel may be limited in a first direction X-X' (or row direction) as indicated by a mark “ⅹ”, while a travel path of the light emitted from a width area of one sub-pixel may be limited in a second direction Y-Y' (or column direction) as indicated by a mark “ⅹ”. When the display apparatus is disposed in the vehicle, the light travel along each of the vertical and horizontal directions may be limited such that the viewing angle in each of the vertical and horizontal directions of the display apparatus may be limited. Accordingly, when the second lens 340-2 is used in the display apparatus in front of the driver's seat, the image therefrom can be individually recognized only by the driver on the driver's seat. Further, when the second lens 340-2 is used in the display apparatus in front of the passenger's seat, the image therefrom can be individually recognized only by the passenger on the passenger's seat.

Referring to FIGS. 7 and 8, one or more display areas may be disposed in the vehicle. The at least one display area may include the first display area 10a and the second display area 10b. In addition, although not shown in the drawings, the third display area 10c (see FIG. 1) disposed in front of the passenger's seat may be disposed.

Referring to FIG. 7, the viewing angle adjustment component may not be disposed in the display panel disposed in the second display area 10b positioned between the first display area 10a and the third display area 10c among the first to third display areas 10a to 10c. Then, an image IMG1 provided from the second display area 10b may reflect onto a first position 20a of the front glass 20 in the frontward and upward direction of the second display area 10b. The image IMG1 reflecting onto the first position 20a may interfere with the field of view of the user (or the driver). In this regard, as shown in FIG. 8, when the viewing angle adjustment component such as the lens as shown in FIG. 5 and FIG. 6 is disposed in the display panel disposed in the second display area 10b, the light travel along the vertical and/or horizontal direction may be limited such that the viewing angle along the vertical and/or horizontal direction of the display panel disposed in the second display area 10b may be limited. Thus, the image IMG1 may not reflect onto the first position 20a. Accordingly, the field of view of the driver may be prevented from being interfered therewith when the driver is driving the vehicle.

The lens protection layer 350 may be disposed on the lens 340. The polarization layer 360 may be disposed on the lens protection layer 350. The lens protective layer 350 may protect the lens 340 disposed thereunder from external foreign substances or the like. The lens protection layer 350 may be referred to as a lens protection member. In addition, the lens protection layer 350 may planarize a step generated by the lens 340. The lens protection layer 350 may extend from the display area DA into a partial area of the bezel area BZA. In an example, the refractive index of the lens protection layer 350 may be lower than the refractive index of the lens 340. Accordingly, light having passed through the lens 340 may be prevented from being reflected toward the substrate 205.

An insulating material having fluidity may be included in the lens protection layer 350. The lens protection layer 350 may include the insulating material having fluidity and thus be formed in a shape having an upper flat surface in the display area DA. An organic insulating material may be included in the insulating material having fluidity. For example, the organic insulating material may include at least one of epoxy, polyimide, polyethylene, and acrylate. However, the material is not limited thereto.

When the insulating material having fluidity flows to the outer area (or edge area) of the display panel 10, a height of a portion of the lens protection layer 350 disposed in a portion of the display area DA closer to the bezel area BZA may be reduced. As a result, the height uniformity between the height of a portion of the lens protection layer 350 in the central area of the display area DA and the height of a portion of the lens protection layer 350 in the portion of the display area DA close to the bezel area BZA may be deteriorated.

Accordingly, the display apparatus according to some embodiments of the present disclosure may include a structure for controlling the flow of the insulating material having fluidity in the bezel area. Hereinafter, this will be described with reference to the drawings.

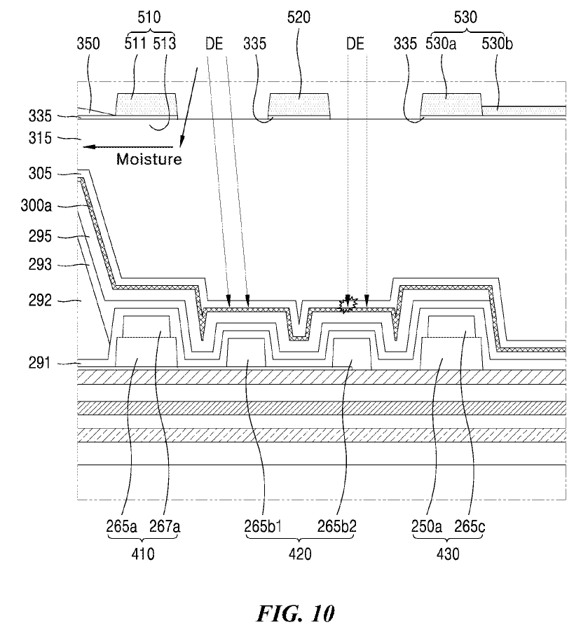

FIGS. 9 and 10 are diagrams illustrating a display apparatus according to an embodiment of the present disclosure. FIG. 9 is a cross-sectional view taken along a line III-III' of FIG. 2. FIG. 10 is an enlarged view of an area V of FIG. 9.

For example, FIG. 9 may show a cross-section of a partial area disposed in one side in the second direction DR2 of the display area DA, and the non-display area NDA of the display panel 10 (see FIG. 2). In FIG. 10, the polarizing layer 360 is excluded for convenience of illustration. Since FIGS. 9 and 10 include the same components as those of FIG. 4, redundant descriptions thereof will be omitted or briefly set forth, and differences therebetween will be mainly described. Like reference numerals may denote like elements.

Referring to FIGS. 9 and 10, the first insulating structure 211 may be disposed on the substrate 205 and in the non-display area NDA. The first insulating structure 211 may include one or more insulating layers extending from the display area DA. For example, the first insulating structure 211 may include the first buffer layer 210, the second buffer layer 220, and the gate insulating layer 230. However, embodiments of the present disclosure are not limited thereto.

The first intermediate electrode layer 236 may be disposed on the first insulating structure 211 and in the non-display area NDA. In an example, the first intermediate electrode layer 236 may act as one of signal lines that transmit various signals. In the present disclosure, for convenience of description, an embodiment in which the first intermediate electrode layer 236 is made of the same material as that of the gate electrode 235 and be formed in the same process as the process for forming the gate electrode 235 will be described. In addition, in the present disclosure, for convenience of description, an embodiment in which the first intermediate electrode layer 236 is embodied as a single layer has been described. However, embodiment of the present disclosure are not limited thereto. For example, the first intermediate electrode layer 236 may be embodied as a stack of a plurality of layers.

The first interlayer insulating layer 237 may be disposed on the first intermediate electrode layer 236 and in the non-display area NDA. The first interlayer insulating layer 237 may include an inorganic insulating material and may extend from the display area DA. The second intermediate electrode layer 238 may be disposed on the first interlayer insulating layer 237 and in the non-display area NDA. The second intermediate electrode layer 238 may act as, for example, one of the signal lines for transmitting various signals. The second intermediate electrode layer 238 may extend into the pad area PDA.

The second interlayer insulating layer 239 may be disposed on the second intermediate electrode layer 238 and in the non-display area NDA. A signal line 245imay be disposed on the second interlayer insulating layer 239. The signal line 245i may be made of the same material as the material of the source/drain electrodes 245 and be formed in the same process as the process for forming the source/drain electrodes 245 (see FIG. 4). A pad electrode 245p made of the same material as that of the signal line 245i and be formed through the same process as the process for forming the signal line 245i may be disposed in the pad area PDA. The pad electrode 245p may be in contact with and electrically connected to the second intermediate electrode layer 238. Although not shown in the drawings, the pad electrode 245p may be connected to the printed circuit board via a flexible circuit board on which the driving circuit chip is disposed. Accordingly, the second intermediate electrode layer 238 may provide, to the display area DA, power or a data signal for driving the light-emitting element supplied from the driver disposed on the printed circuit board.

The planarization layer 250 may be disposed on the signal line 245i. The planarization layer 250 may be disposed in the display area DA and a portion of the bezel area BZA. For example, a portion of the planarization layer 250 may act as a pad protection pattern 250p covering one side end of the pad electrode 245p. The first electrode 260 extending from the display area DA may be disposed on the planarization layer 250 and in the non-display area NDA. The first electrode 260 may extend into a portion of the bezel area BZA. The bank 265 may be disposed on the first electrode 260 and in the non-display area NDA. The bank 265 may extend into a portion of the bezel area BZA.

A plurality of barrier patterns and a plurality of encapsulation dams 400 may be disposed in the bezel area BZA.

The bezel area BZA may include a first bezel area BZA1 and a second bezel area BZA2. For example, as illustrated in FIG. 2, the first bezel area BZA1 may be positioned in one side in the second direction DR2 of the display panel 10. The second bezel area BZA2 may be positioned in each of the other side in the second direction DR2, and both opposing sides in the first direction DR1 of the display panel 10. For example, the pad area PDA in which a plurality of pad electrodes 245p are disposed may be positioned in the first bezel area BZA1.

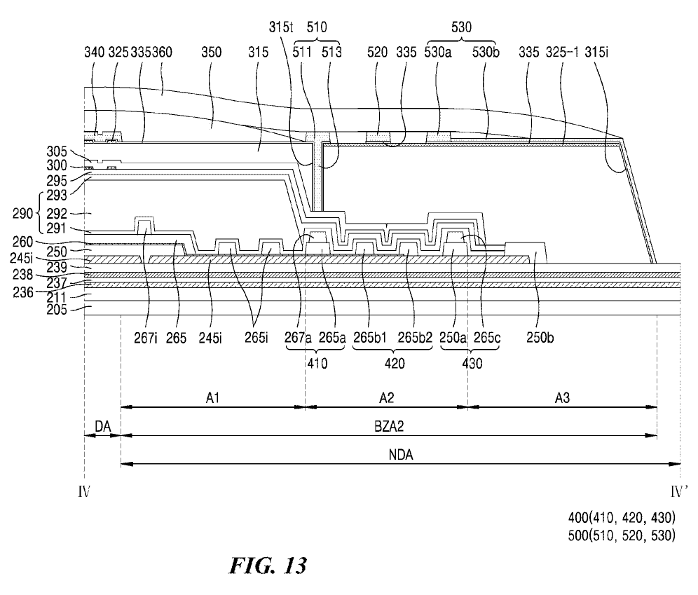

Each of the first bezel area BZA1 and the second bezel area BZA2 may include a first area A1, a second area A2, and a third area A3. The first area A1 of the first bezel area BZA1 and the second bezel area BZA2 may be an area closest to the display area DA among the first to third areas. The third area A3 of the first bezel area BZA1 and the second bezel area BZA2 may be an area closest to an edge portion (or an end) of the substrate 205 among the first to third areas. For example, as illustrated in FIG. 9, the third area A3 of the first bezel area BZA1 may be closer to the pad area PDA than each of the first and second areas A1 and A2 is. As illustrated in FIG. 13, the third area A3 of the second bezel area BZA2 may be an area closest to the end of the substrate 205 among the first to third areas. The second area A2 may be disposed between the first area A1 and the third area A3.

The plurality of barrier patterns and the plurality of encapsulation dams 400 may prevent the second encapsulation layer 292 including the organic insulating material from overflowing outwardly of the first bezel area BZA1 and the second bezel area BZA2.

The plurality of barrier patterns may include a first barrier pattern 267i, a second barrier pattern 265i, and a third barrier pattern 250b. The first barrier pattern 267i may be positioned on the bank 265 and disposed in the first area A1 closest to the display area DA. The first barrier pattern 267i may be made of the same material as that of the spacer 267 and be formed through the same process as the process for forming the spacer 267 (see FIG. 4) of the display area DA.

The plurality of encapsulation dams 400 may include a first encapsulation dam 410, a second encapsulation dam 420, and a third encapsulation dam 430. The first encapsulation dam 410, the second encapsulation dam 420, and the third encapsulation dam 430 may be arranged to be spaced apart from each other by a predetermined spacing in a direction from the first area adjacent to the display area DA of the first bezel area BZA1 and the second bezel area BZA2 to the side end of the substrate 205 or the display panel. The plurality of encapsulation dams 400 may also be referred to as the plurality of first structures.

The first encapsulation dam 410 may be disposed in a boundary area between the first area A1 and the second area A2. The first encapsulation dam 410 may have a structure in which a first layer 265a as a lower layer and a second layer 267a as an upper layer are stacked. For example, the first layer 265a may be made of the same material as that of the bank 265 and be formed in the same process as the process for forming the bank 265. The second layer 267a may be made of the same material as that of the first barrier pattern 267i and be formed through the same process as the process for forming the first barrier pattern 267i.

The second barrier pattern 265i may be disposed in the first area A1. For example, the second barrier pattern 265i may be disposed between the first encapsulation dam 410 and the first barrier pattern 267i. The second barrier pattern 265imay be made of the same material as that of the bank 265 and be formed in the same process as the process for forming the bank 265. In an example, the second barrier pattern 265i may be disposed such that a plurality of patterns are spaced apart from each other.

The third encapsulation dam 430 may be disposed in a boundary area between the second area A2 and the third area A3 of the first bezel area BZA1 and the second bezel area BZA2. The third encapsulation dam 430 may be spaced apart from the first encapsulation dam 410 while the third encapsulation dam 430 is disposed between the first encapsulation dam 410 and the side end of the substrate 205. The third encapsulation dam 430 may have a structure in which a first layer 250a as a lower layer and a second layer 265c as an upper layer are stacked. For example, the first layer 250aof the third encapsulation dam 430 may be made of the same material as that of the planarization layer 250 and be formed in the same process as the process for forming the planarization layer 250. The second layer 265c of the third encapsulation dam 430 may be made of the same material as that of the bank 265 and be formed in the same process as the process for forming the bank 265.

The second encapsulation dam 420 may be disposed between the first encapsulation dam 410 and the third encapsulation dam 430. The second encapsulation dam 420 may include a plurality of patterns spaced apart from each other in the horizontal direction. The plurality of patterns may be made of the same material as that of the bank 265 and be formed in the same process as the process for forming the bank 265. The plurality of patterns may include a first pattern 265b1 and a second pattern 265b2. However, embodiments of the present disclosure are not limited thereto, and at least three patterns may be included therein. Each of the first pattern 265b1 and the second pattern 265b2 may have a line shape extending along the periphery of the display area DA and surrounding the display area DA. The second pattern 265b2 may be positioned outwardly of the first pattern 265b1, and the second pattern 265b2 may be positioned inwardly of the third encapsulation dam 430.

The third barrier pattern 250b may be disposed outwardly of the third encapsulation dam 430. For example, the third barrier pattern 250b may be disposed in the third area A3 as an edge area of the first bezel area BZA1 and the second bezel area BZA2. The third barrier pattern 250b may be made of the same material as that of the planarization layer 250 and be formed through the same process as the process for forming the planarization layer 250. The third barrier pattern 250b may cover an end of the signal line 245i extending into the first bezel area BZA1 and the second bezel area BZA2.

Each of the first encapsulation layer 291, the second encapsulation layer 292, and the third encapsulation layer 293 may extend from the display area DA into the first bezel area BZA1 and the second bezel area BZA2. The first encapsulation layer 291 may cover the first barrier pattern 267i, the second barrier pattern 265i, the first encapsulation dam 410, the second encapsulation dam 420, and the third encapsulation dam 430. The third encapsulation layer 293 may be disposed on the second encapsulation layer 292 in the first area A1 of the first bezel area BZA1 and the second bezel area BZA2, and may be in contact with the first encapsulation layer 291 in the second area A2 and the third area A3. An inorganic insulating material may be included in each of the first encapsulation layer 291 and the third encapsulation layer 293. The second encapsulation layer 292 may be disposed between the first encapsulation layer 291 and the third encapsulation layer 293.

The first touch buffer layer 295 may be disposed on the third encapsulation layer 293 and in the non-display area NDA. The first touch buffer layer 295 may include an inorganic insulating material.

A plurality of bridge electrodes 300 may be disposed on the first touch buffer layer 295. Some areas of the plurality of bridge electrodes 300 may extend into the first bezel area BZA1 and then into the pad area PDA. A partial area of the bridge electrode 300 extending into the first bezel area BZA1 and the pad area PDA may be referred to as a bridge link line 300a. The bridge link line 300a may be in contact with and electrically connected to the pad electrode 245p in the pad area PDA. The bridge link line 300a may transmit a touch driving signal from the driving circuit chip or the driver disposed on the printed circuit board to the display area DA. Accordingly, the bridge link line 300a may be disposed in one side in the second direction DR2 of the display panel DP as shown in FIG. 9, and may not be disposed in each of the other side in the second direction DR2 and both opposing sides in the first direction DR1 of the display panel.

The second touch buffer layer 305 may be disposed on the plurality of bridge electrodes 300 and the bridge link line 300a. The second touch buffer layer 305 may extend into the first bezel area BZA1 and the second bezel area BZA2 while covering the plurality of bridge electrodes 300 and the bridge link line 300a. The second touch buffer layer 305 may be conformally formed on each of the first touch buffer layer 295 and the third encapsulation layer 293 disposed thereunder. The second touch buffer layer 305 may cover the bridge link line 300a disposed in the pad area PDA. The second touch buffer layer 305 may include an inorganic insulating material.

The touch insulating layer 315 may be disposed on the second touch buffer layer 305 and in the non-display area NDA. The touch insulating layer 315 may extend from the display area DA into the first bezel area BZA1 and the second bezel area BZA2. A side end of the touch insulating layer 315 extending into the first bezel area BZA1 and the second bezel area BZA2 may be implemented to have an inclined surface 315i having a slope. In addition, in the first bezel area BZA1, the side end of the touch insulating layer 315 may define a boundary area between the third area A 3 and the pad area PDA. In addition, in the second bezel area BZA 2, the side end of the touch insulating layer 315 may be positioned inwardly the side end of the substrate 205. For example, the side end of the touch insulating layer 315 may be positioned in the third area A3 of the first bezel area BZA1 and the second bezel area BZA2.

The touch insulating layer 315 may have a sufficient thickness to planarize a step caused by the underlying structure. The touch insulating layer 315 may include an organic insulating material. The plurality of touch electrodes 325 may be disposed on the touch insulating layer 315 and in the display area DA. The passivation layer 335 may be disposed on the touch electrode 325 and in the non-display area NDA. The passivation layer 335 may extend from the display area DA into the first bezel area BZA1 and the second bezel area BZA2. The passivation layer 335 may be disposed on an upper surface of the touch insulating layer 315 made of an organic insulating material in the first bezel area BZA1 and the second bezel area BZA2. The passivation layer 335 may not cover a portion of an upper surface of the touch insulating layer 315 so as to be exposed in the second area A2 of the first bezel area BZA1 and the second bezel area BZA2. The passivation layer 335 may cover the inclined surface 315i of the touch insulating layer 315 in the third area A3 of the first bezel area BZA1 and the second bezel area BZA2. The passivation layer 335 may be made of an inorganic insulating material to prevent moisture or foreign matter from penetrating into the touch insulating layer 315.

The lens 340 may be disposed on the passivation layer 335 and in the display area DA. The portion of the display area DA illustrated in FIG. 9 may be an edge portion of the display area DA adjacent to the first bezel area BZA1. Accordingly, the lens 340 disposed in the edge portion of the display area DA may act as a dummy pattern.

The lens protection layer 350 may be disposed on the lens 340. The lens protection layer 350 may be formed by applying an insulating material having fluidity to planarize a step caused by the lens 340 or the like disposed thereunder. When a structure controlling the flow of the insulating material having the fluidity is absent in the first bezel area BZA1 and the second bezel area BZA2, the insulating material having the fluidity may spread into the outer area of the display panel due to the fluidity of the material. For example, the insulating material having fluidity may flow to the third area A3 of the first bezel area BZA1 and the second bezel area BZA2 adjacent to the side end of the substrate 205. As a result, the height of the portion of the lens protection layer 350 in the edge of the display area DA close to the first bezel area BZA1 and the second bezel area BZA2 may be reduced. Thus, the height uniformity of the lens protection layer 350 in the entire area of the display area DA may deteriorate.

Accordingly, the structure for controlling the flow of the insulating material having fluidity may be disposed on the passivation layer 335 and in the first bezel area BZA1 and the second bezel area BZA2. For example, the structure for controlling the flow of the insulating material having fluidity may be embodied as the plurality of lens dams 500. The plurality of lens dams 500 may include a first lens dam 510, a second lens dam 520, and a third lens dam 530. Adjacent ones of the first, second and third lens dams 510, 520, and 530 may be arranged to be spaced apart from each other by a predetermined spacing. For example, each of the first, second and third lens dams 510, 520, and 530 may have a line shape continuously extending around the display area DA in the plan view. That is, each of the first, second and third lens dams 510, 520, and 530 may extend so as not to be broken but to form a closed loop in the plan view. In an example, the plurality of lens dams 500 may have the same thickness. However, embodiments of the present disclosure are not limited thereto.

Each of the plurality of lens dams 500 may be made of the same material as that of the lens 340 and be formed in the same process as the process for forming the lens 340 of the display area DA. Accordingly, the display apparatus according to some embodiment of the present disclosure may reduce the number of the process steps, such that there is an effect that the production energy required for the production of the display apparatus may be reduced, thereby reducing greenhouse gas emissions.

The plurality of lens dams 500 may be positioned in the first bezel area BZA1 and the second bezel area BZA2. At least one of the plurality of lens dams 500 may be disposed in the second area A2 of the first bezel area BZA1 and the second bezel area BZA2 in which the first, second and third encapsulation dams 410, 420, and 430 are disposed.

The passivation layer 335 may include an open area. The open area may expose a portion of the upper surface of the touch insulating layer 315 in the second area A2 of the first bezel area BZA1 and the second bezel area BZA2. For example, the open area may be disposed between the first lens dam 510 and the second lens dam 520 and between the second lens dam 520 and the third lens dam 530.

The open area may be formed by removing a portion of the passivation layer 335 between the adjacent ones of the first, second and third lens dams 510, 520, and 530 in a process of forming the plurality of lens dams 500 using one lens mask. The plurality of lens dams 500 may be formed in a dry etching process. The process of using one lens mask may simplify the process and reduce a manufacturing cost.

However, over-etching on a portion of the thin passivation layer 335 disposed between adjacent ones of the first, second and third lens dams 510, 520, and 530 may occur. The over-etching may be a phenomenon in which etching is further performed to a layer disposed under a etch stop point. Accordingly, the portion of the passivation layer 335 between the adjacent ones of the first, second and third lens dams 510, 520, and 530 may be removed to expose a portion of the upper surface of the touch insulating layer 315 which is made of the organic insulating material. Moisture may penetrate into the organic insulating material in a high temperature and high humidity environment. As shown using an arrow in FIG. 10, the touch insulating layer 315 made of the organic insulating material may act as a moisture penetration path through which the moisture flows. The touch insulating layer 315 extends into the display area DA, such that the metal lines in the display area DA may be exposed to the moisture. When the metal line such as a touch line in the display area DA is exposed to the moisture, there may be a problem in that the metal line undergoes electrolytic corrosion or is corroded.

In addition, the over-etching is further performed, such that, as indicated by another arrow in FIG. 10, the second touch buffer layer 305 under the touch insulating layer 315 may be damaged by a dry etching source DE. When the second touch buffer layer 305 including the inorganic insulating material is damaged, a problem in which a function of the bridge link line 300a under the second touch buffer layer 305 is weakened may occur. When the function of the bridge link line 300a is weakened, it is difficult for the bridge link line 300a to normally transmit the touch driving signal to the display area DA, so that a product defect may occur, and reliability of the product may be deteriorated.

Accordingly, the display apparatus according to the embodiment of the present disclosure may include a structure that prevents the touch insulating layer 315 from acting as the moisture penetration path. In addition, the display apparatus according to an embodiment of the present disclosure may include a structure that prevents the second touch buffer layer 305 from being damaged by the dry etching source. Hereinafter, this will be described with reference to the drawings.

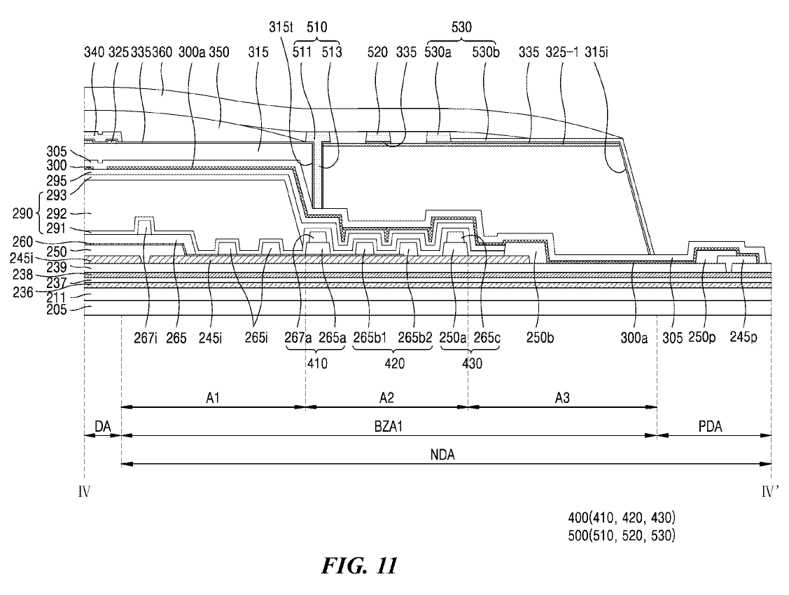

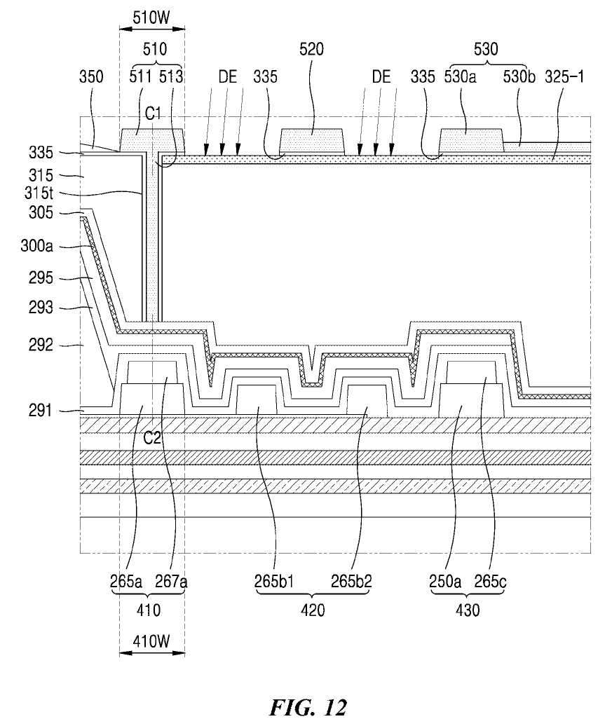

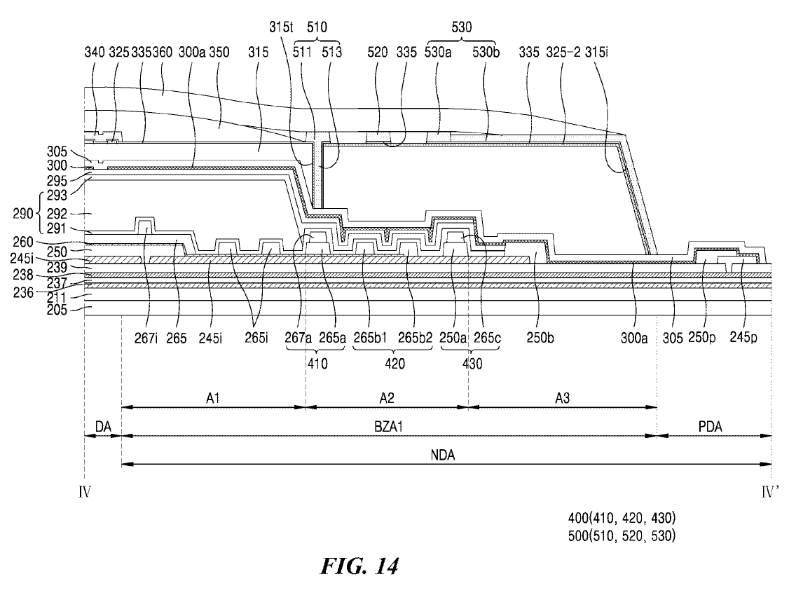

FIGS. 11-13 are respectively diagrams illustrating display apparatuses according to some further embodiments of the present disclosure. FIG. 11 is a cross-sectional view taken along a line III-III' of FIG. 2. FIG. 12 is an enlarged view of an area VI of FIG. 11. FIG. 13 is a cross-sectional view taken along a line IV-IV' of FIG. 2. FIG. 14 is a diagram illustrating a modified example of a shield pattern according to an embodiment of the present disclosure.

For example, FIG. 11 may show a cross-section of a partial area of the display area DA and the non-display area disposed in one side in the second direction DR2 of the display panel 10 (see FIG. 2). FIG. 13 may show a cross-section of a partial area of the display area DA and the non-display area disposed in each of the other side in the second direction DR2 and both opposing sides in the first direction DR1 of the display panel 10 (see FIG. 2). In FIG. 12, the polarizing layer 360 is excluded for convenience of illustration. Since FIGS. 11 and 13 include the same components as those of FIGS. 9 and 10, redundant descriptions thereof will be omitted or briefly set forth, and differences therebetween will be described. Like reference numerals may denote like elements.

Referring to FIGS. 11-13, the plurality of encapsulation dams 400 may be disposed on the second area A2 of the first bezel area BZA1 and the second bezel area BZA2. The plurality of encapsulation dams 400 may include the first encapsulation dam 410, the second encapsulation dam 420, and the third encapsulation dam 430. The plurality of encapsulation dams 400 may be covered with the encapsulation portion 290 having a multi-layered insulating structure. The bridge link line 300amay be disposed on the encapsulation portion 290. The bridge link line 300a may be covered with the second touch buffer layer 305. The second touch buffer layer 305 may include an inorganic insulating material. The touch insulating layer 315 including the organic insulating material may be disposed on the second touch buffer layer 305.

At least one trench 315t may be defined in the touch insulating layer 315. The trench 315t may vertically extend through the touch insulating layer 315 in a direction toward the substrate 205 and may expose a portion of an upper surface of the second touch buffer layer 305. The trench 315t may have a pillar shape vertically extending through the touch insulating layer 315 in a cross-sectional view. The trench 315t may be disposed to overlap the first encapsulation dam 410 of the plurality of encapsulation dams 400 in the vertical direction. The trench 315t may have a ring shape surrounding an outer periphery of the display area DA in the plan view. For example, the trench 315t may have a closed loop line shape in the plan view. The touch insulating layer 315 may be divided into two portions around the trench 315t interposed therebetween. Thus, the two portions thereof may be spaced or isolated from each other via the trench 315t.

A plurality of touch electrodes 325 may be disposed on the touch insulating layer 315 in the display area DA. A shield pattern 325-1 may be disposed on a partial area of the first bezel area BZA1 and the second bezel area BZA2 while being spaced apart from the plurality of touch electrodes 325 in the direction from the lens to the side end of the substrate. The shield pattern 325-1 may be made of the same material as that of the touch electrode 325 of the display area DA and be formed in the same process as that for forming the touch electrode 325 of the display area DA. The shield pattern 325-1 may include a single layer or multiple layers made of any one of molybdenum (Mo), aluminum (Al), chromium (Cr), gold (Au), titanium (Ti), nickel (Ni), neodymium (Nd), and copper (Cu) or an alloy thereof. For example, the shield pattern 325-1 may have a stacked structure of titanium layer/aluminum layer/titanium layer (Ti/Al/Ti).

As described above, the touch insulating layer 315 may be divided into two portions around the trench 315t interposed therebetween. Thus, the two portions thereof may be spaced or isolated from each other via the trench 315t and may include an inner portion closer to the display area and an outer portion closer to the side end of the substrate. In this regard, the shield pattern 325-1 may be disposed on the outer portion of the touch insulating layer 315. For example, the shield pattern 325-1 may be disposed on the touch insulating layer 315 in the second area A2 and the third area A3 of the first bezel area BZA1 and the second bezel area BZA2. The shield pattern 325-1 may prevent the touch insulating layer 315 and the second touch buffer layer 305 from being damaged by the dry etching source DE.

The passivation layer 335 may be disposed on the touch electrode 325 in the display area and on a partial area of the shield pattern 325-1 in the non-display area. The passivation layer 335 may include the inorganic insulating material. The passivation layer 335 may be disposed on a portion of the surface of the touch insulating layer 315 exposed through the trench 315t.

The lens 340 may be disposed on the passivation layer 335 in the display area DA. The plurality of lens dams 500 may be disposed in the first bezel area BZA1 and the second bezel area BZA2 spaced apart from the lens 340. The plurality of lens dams 500 may prevent the organic insulating material constituting the lens protection layer 350 from overflowing.

The plurality of lens dams 500 may include the first lens dam 510, the second lens dam 520, and the third lens dam 530 spaced apart from each other. The first lens dam 510, the second lens dam 520, and the third lens dam 530 may be arranged to be spaced apart from each other in the direction from the lens to the side end of the substrate 205. Referring to FIG. 11, the first lens dam 510 may be disposed to overlap the first encapsulation dam 410 disposed in the second area A2 in the vertical direction, but is not limited thereto. For another example, the first lens dam 510 may be disposed to overlap the second encapsulation dam 420 or the third encapsulation dam 430. The first lens dam 510 may include a first head portion 511 and a first pillar portion 513. The first pillar portion 513 of the first lens dam 510 may fill the trench 315t. The first head portion 511 of the first lens dam 510 may be integrally formed with the first pillar portion 513 and may be disposed on the top surface of the first pillar portion 513. The first head portion 511 may extend on and along the upper surface of the touch insulating layer 315.

The trench 315t may have the same shape as that of the first pillar portion 513 of the first lens dam 510 in the cross-sectional view. In a plan view, the trench 315t may have a line shape continuously extending around the display area DA. That is, in the plan view, the trench 315t may extend so as not be broken but to form a closed loop.

For example, a first width 510w of a bottom surface of the first head portion 511 of the first lens dam 510 may have a size in a range of 40 ㎛ to 55 ㎛. In this regard, the width may refer to a width in the direction from the lens to the side end of the substrate. However, embodiments of the present disclosure are not limited to the above numerical value. A height of the first head portion 511 of the first lens dam 510 may be smaller than the first width 510w. The height of the first head portion 511 may be a vertical length between the upper surface of the touch insulating layer 315 and an upper surface of the first head portion 511. For example, the height of the first head portion 511 of the first lens dam 510 may be in a range of 10 ㎛ to 15 ㎛. Each of the width and the height of each of the second lens dam 520 and the third lens dam 530 may be equal to each of the first width 510w and the height of the first head portion 511 of the first lens dam 510. Accordingly, the width of each of the first, second and third lens dams 510, 520, and 530 may be greater than the height thereof. In this case, the contact area of the polarizing layer 360 to be described later in contact with each of the first, second and third lens dams 510, 520, and 530 increases, the occurrence of the peel-off defect of the polarizing layer 360 may be prevented.

The first lens dam 510 may be a structure which the insulating material having fluidity spreading from the display area DA first contacts in the first bezel area BZA1 and the second bezel area BZA2.

Therefore, it is preferable that an upper surface of the first head portion 511 of the first lens dam 510 is positioned at a higher vertical level than a vertical level of an upper surface of each of the second and third lens dams 520 and 530.

For example, when a portion of the upper surface of the first head portion 511 of the first lens dam 510 corresponding to the largest thickness and a portion of an upper surface of the first encapsulation dams 410 disposed thereunder corresponding to the largest thickness overlap each other in the vertical direction, the upper surface of the first head portion 511 of the first lens dam 510 may be positioned at a higher vertical level than a vertical level of an upper surface of each of the second and third lens dams 520 and 530. The height of the first head portion 511 of the first lens dam 510 may be maintained at a size capable of controlling the flow of the flowable insulating material. As a result, the first head portion 511 of the first lens dam 510 may first prevent the insulating material having fluidity from overflowing over the second lens dam 520 or the third lens dam 530. For example, the portion of the upper surface of the first head portion 511 of the first lens dam 510 corresponding to the largest thickness may be a central portion thereof through which a first center line C1 of the first width 510w vertically passes. In addition, the first encapsulation dam 410 may have a second width 410w which may be a width of a bottom surface of the first encapsulation dam 410 in the direction from the lens to the side end of the substrate, and the portion of the upper surface of the first encapsulation dam 410 corresponding to the greatest thickness may be a central portion thereof through which a second central line C2 of the second width 410w vertically passes. Each of the first center line C1 and the second center line C2 may be a virtual line vertically passing through each of the first lens dam 510 and the first encapsulation dam 410. The first center line C1 may coincide with a center line vertically passing through a center in a width direction of the first pillar portion 513 of the first lens dam 510. However, embodiments of the present disclosure are not limited thereto.

The first center line C1 of the first width 510w of the first head portion 511 of the first lens dam 510 may coincide with the second center line C2 of the second width 410w of the first encapsulation dam 410. Accordingly, the flow of the insulating material having fluidity may be controlled by the first lens dam 510 overlapping the first encapsulation dam 410 in the vertical direction and having the upper surface positioned at a higher vertical level than a vertical level of an upper surface of each of the second and third lens dams 520 and 530.

The passivation layer 335 may not cover a portion of an upper surface of the shield pattern 325-1 so as to be exposed in the second area A2 of the first bezel area BZA1 and the second bezel area BZA2. The shield pattern 325-1 may prevent the touch insulating layer 315 which is made of the organic insulating material from being exposed in the process of forming the plurality of first, second and third lens dams 510, 520, and 530. Moisture may penetrate into the organic insulating material in a high temperature and high humidity environment. Thus, the touch insulating layer 315 made of the organic insulating material may act as a moisture penetration path through which the moisture flows. The touch insulating layer 315 extends into the display area DA, such that the metal lines in the display area DA may be exposed to the moisture. When the metal line such as a touch line in the display area DA is exposed to the moisture, there may be a problem in that the metal line undergoes electrolytic corrosion or is corroded.

Accordingly, in the display apparatus according to another embodiment of the present disclosure, the touch insulating layer 315 may be divided into two portions around the trench 315t interposed therebetween. Thus, the two portions thereof may be spaced or isolated from each other via the trench 315t. Thus, the trench 315t may prevent the touch insulating layer 315 from acting as the moisture penetration path. For example, as shown in FIGS. 11 and 12, the trench 315t may be disposed at a position between the first area A1 relatively close to the display area DA and the second area A2. The trench 315tmay divide the touch insulating layer 315 into two portions isolated from each other. Thus, the trench 315t may interrupt the continuity of the touch insulating layer 315 and may allow the touch insulating layer 315 to be broken or discontinuous. Accordingly, the trench 315t may block the flow of the moisture penetrating through the exposed portion of the upper surface of the touch insulating layer 315 disposed between the first lens dam 510 and the second lens dam 520 so as not to invade into the display area DA.

In addition, the surface of the touch insulating layer 315 exposed through the trench 315t may be covered with the passivation layer 335 made of the inorganic insulating material. Accordingly, the flow of the moisture into the display area may be prevented by the passivation layer 335. In addition, the trench 315t may be filled with the first lens dam 510. The first lens dam 510 may include an organic insulating material having a second density that is relatively higher than a first density of the touch insulating layer 315. Accordingly, the trench 315tfilled with the first lens dam 510 may prevent moisture from permeating therethrough. Accordingly, the display apparatus satisfying a high reliability may be realized by preventing the moisture permeating from the outside from flowing toward the display area DA. In an example, the trench 315t may have a pillar shape extending through the touch insulating layer 315 and extending in a line coinciding with the first center line C1 and the second center line C2.

In addition, the shield pattern 325-1 may cover the exposed portion of the upper surface of the touch insulating layer 315 disposed between the adjacent ones of the plurality of lens dams 500, thereby preventing moisture from penetrating into the touch insulating layer 315. In addition, the shield pattern 325-1 may function as an etch stop film in a dry etching process for forming the plurality of lens dams 500 to prevent the over-etching. The shield pattern 325-1 may prevent the dry etching source DE from damaging the touch insulating layer 315 and the lower second touch buffer layer 305. Accordingly, the shield pattern 325-1 may prevent a product defect from occurring due to the weakening of the function of the bridge link line 300a.

In an example, a bottom surface of the first head portion 511 of the first lens dam 510 may be divided into a first area disposed on one side of the first pillar portion 513 and closer to the display area, a second area overlapping the first pillar portion 513, and a third area disposed on the other side of the first pillar portion 513 and away from the display area. The shield pattern 325-1 may be disposed under the first head portion 511 of the first lens dam 510 so as to overlap the third area of the bottom surface of the first head portion 511 of the first lens dam 510 in the vertical direction. This may prevent the touch insulating layer 315 from being exposed in the boundary area between the first head portion 511 and the shield pattern 325-1. The shield pattern 325-1 may extend onto a side end of the touch insulating layer 315. For example, a side end of the shield pattern 325-1 may be aligned with the side end of the touch insulating layer 315.

If the first lens dam 510 is disposed in the third area A3 that is positioned outwardly of the second area A2 in which the first, second and third encapsulation dams 410, 420, and 430 are disposed, the insulating material having fluidity flows to the third area A3. Then, the uniformity between the thickness of the portion of the lens protection layer 350 in the central area of the display area DA and the thickness of the portion of the lens protection layer 350 in the edge portion of the display area DA close to the first bezel area BZA1 and the second bezel area BZA2 may be deteriorated. Then, since the thickness of the lens protection layer 350 is not sufficiently secured in the edge area of the display area, there is a problem in that a portion of the lens 340 in the edge area of the display area is not protected by the lens protection layer 350 occurs. In addition, if the first, second and third lens dams 510, 520, and 530 are disposed in the third area A3, a problem in which the insulating material having fluidity overflows may occur. Accordingly, it is preferable that at least one of the plurality of lens dams 500 is disposed in the second area A2 in which the first, second and third encapsulation dams 410, 420, and 430 are disposed.

The second lens dam 520 may be disposed outwardly of the first lens dam 510. The third lens dam 530 may be disposed outwardly of the second lens dam 510. The third lens dam 530 may include a first pattern portion 530aand a second pattern portion 530b. The first pattern portion 530a may have the same shape as that of the first head portion 511 of the first lens dam 510 or the second lens dam 520. For example, the first pattern portion 530a may have a trapezoidal shape in the cross-sectional view. However, embodiments of the present disclosure are not limited thereto.

The second pattern portion 530b of the third lens dam 530 may be embodied as an extension pattern extending outwardly from one side surface of the first pattern portion 530a. The second pattern portion 530b may extend toward the edge portion (or the side end) of the substrate 205. For example, the second pattern portion 530b may extend along and on the inclined surface 315i of the touch insulating layer 315. The touch electrode 325 may extend from the display area DA onto the edge portion (or the side end) of the substrate 205.

The second pattern portion 530b may cover the touch electrode (or a metal line) positioned on an edge area (or the end area) of the substrate 205 to prevent damage to the touch electrode from external impact, moisture penetration, or the like. This may prevent the occurrence of the touch operation failure due to damage to the touch electrode, thereby improving product reliability. The first pattern portion 530a and the second pattern portion 530b may be integrally formed with each other. The second pattern portion 530b may be formed in a halftone manner.

The polarization layer 360 may be disposed on the lens protection layer 350. The polarizing layer 360 may disposed across the display area DA, and the first area A1, the second area A2, and the third area A3 of the first bezel area BZA1 and the second bezel area BZA2. The lens protection layer 350 may not be disposed beyond the first area A1 of the first bezel area BZA1 and the second bezel area BZA2. In addition, the upper surface of the second pattern portion 530b disposed in the third area A3 may be positioned at a lower vertical level than a vertical level of the upper surface of the first pattern portion 530a. Accordingly, the upper surface of the display area DA and the upper surfaces of the first area A1 to the third area A3 of the first bezel area BZA1 and the second bezel area BZA2 may be disposed at different vertical levels.

The plurality of lens dams 500 may be disposed between the first area A1 and the third area A3. For example, the plurality of lens dams 500 may be disposed in the second area A2. The polarizing layer 360 may continuously extend across the first area A1 to the third area A3 while being in contact with the plurality of lens dams 500 disposed in the second area A2. The polarizing layer 360 may be gradually inclined downwardly as the polarizing layer 360 extends from the first area A1 toward the third area A3. The polarizing layer 360 may be attached in close contact to the second pattern portion 530b of the third lens dam 530 disposed in the edge portion of the third area A3 and thus may not lift off. Accordingly, a defect in which the polarizing layer 360 lifts off due to a step may be prevented from occurring.

In another example, the shape of the shield pattern may be modified to prevent moisture from penetrating into the display area in the lateral direction of the touch insulating layer 315. For example, as shown in FIG. 14, a shield pattern 325-2 may extend in the first bezel area BZA1 and the second bezel area BZA2 so as to cover the inclined surface 315i of the side end of the touch insulating layer 315. The shield pattern 325-2 may continuously extend so as to cover the exposed portion of the upper surface of the touch insulating layer 315 disposed between the adjacent lens dams 500 and the inclined surface 315i of the side end of the touch insulating layer 315. Accordingly, the shield pattern 325-2 may prevent the moisture from penetrating into the first bezel area BZA1 and the second bezel area BZA2 through the inclined surface 315i of the touch insulating layer 315.

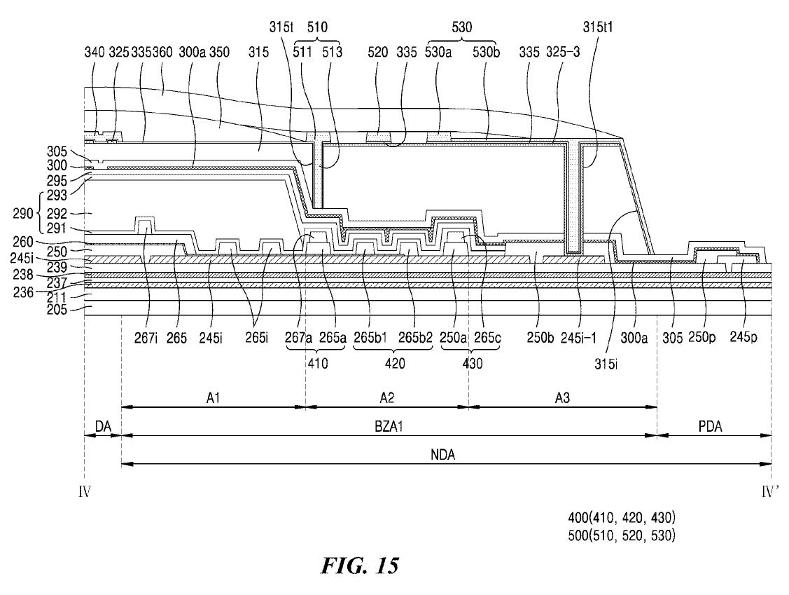

In still another example, the shield pattern may prevent static electricity from being introduced into the display panel. Hereinafter, this will be described with reference to FIG. 15.

FIG. 15 is a diagram illustrating a display apparatus according to still another embodiment of the present disclosure. For example, FIG. 15 may show a cross-section of a partial area of the display area DA and the non-display area disposed in one side in the second direction DR2 of the display panel 10 (see FIG. 2). Since FIG. 15 includes the same components as those of FIGS. 11-13, redundant descriptions thereof will be omitted or briefly set forth, and differences therebetween will be described. Like reference numerals may denote like elements.

Referring to FIG. 15, the first insulating structure 211, the first intermediate electrode layer 236, the first interlayer insulating layer 237, the second intermediate electrode layer 238, and the second interlayer insulating layer 239 may be sequentially stacked on the upper surface of the substrate 205 in an upward direction.

A plurality of signal lines may be disposed on the second interlayer insulating layer 239. The plurality of signal lines may include the same material as that of each of the source/drain electrodes 245 (see FIG. 4) and may be formed in the same process as the process for forming the source/drain electrodes 245. One signal line 245i among the plurality of signal lines may transmit signals or voltages to pixels in the display area DA. The other signal line 245i-1 among the plurality of signal lines may be connected to a ground line. One signal line 245i may be referred to as a first signal line 245i, and the other signal line 245i-1 may be referred to as a second signal line 245i-1.

A plurality of barrier patterns and a plurality of encapsulation dams 400 may be disposed on the plurality of signal lines. The plurality of encapsulation dams 400 may be disposed in the second area A2 of the first bezel area BZA1 and the second bezel area BZA2. The plurality of encapsulation dams 400 may include the first encapsulation dam 410, the second encapsulation dam 420, and the third encapsulation dam 430. The plurality of encapsulation dams 400 may be covered with the encapsulation portion 290 formed to have a multi-layered insulating structure. The bridge link line 300a may be disposed on the encapsulation portion 290. The bridge link line 300a may be covered with the second touch buffer layer 305. The second touch buffer layer 305 may include the inorganic insulating material. The touch insulating layer 315 including the organic insulating material may be disposed on the second touch buffer layer 305.

A plurality of trenches may be defined in the touch insulating layer 315. A first trench 315tand a second trench 315t1 may be included in the plurality of trenches.. Each of the plurality of trenches may extend through the touch insulating layer 315 in the direction toward the substrate 205 as the thickness direction of the touch insulating layer 315. The first trench 315t may be disposed in the boundary area between the first and second areas A1 and A2 in the second area A2. The first trench 315t may expose a portion of the upper surface of the second touch buffer layer 305. The second trench 315t1 may expose a portion of the upper surface of the second signal line 245i-1 connected to the ground line. The second trench 315t1 may be positioned in the third area A3 as an edge portion of the first bezel area BZA1 and the second bezel area BZA2.

The first trench 315t may have a pillar shape vertically extending through the touch insulating layer 315 in a cross-sectional view. The first trench 315t may be disposed to overlap the first encapsulation dam 410 of the plurality of encapsulation dams 400 in the vertical direction. In the plan view, the first trench 315t may have a closed loop line shape surrounding the outer periphery of the display area DA. The touch insulating layer 315 may be divided into both opposing portions in the direction from the lens to the side end of the substrate by the first trench 315t with the first trench 315t interposed therebetween. The two opposing portions may be spaced from each other via the first trench 315t interposed therebetween. The two opposing portions include an inner portion adjacent to the display area and an outer portion adjacent to the side end of the display panel.

The plurality of touch electrodes 325 may be disposed on the touch insulating layer 315 in the display area DA. A shield pattern 325-3 may be disposed in a partial area of the first bezel area BZA1 and the second bezel area BZA2 while being spaced apart from the plurality of touch electrodes 325. The shield pattern 325-3 may be made of the same material as that of the touch electrode 325 of the display area DA and be formed in the same process as the process for forming the touch electrode 325 of the display area DA.

As described above, the touch insulating layer 315 may be divided into both opposing portions in the direction from the lens to the side end of the substrate by the first trench 315t with the first trench 315t interposed therebetween. The both opposing portions may be spaced from each other via the first trench 315t interposed therebetween. The both opposing portions include an inner portion adjacent to the display area and an outer portion adjacent to the side end of the display panel. In this regard, the shield pattern 325-3 may be disposed on the outer portion of the touch insulating layer 315. For example, the shield pattern 325-3 may extend from the second area A2 into the third area A3 of the first bezel area BZA1 and the second bezel area BZA2.

The shield pattern 325-3 may be disposed along and on the surface of the touch insulating layer 315 exposed through the second trench 315t1 and may extend onto the side end of the touch insulating layer 315. The shield pattern 325-3 may extend along and on a side wall and a bottom surface of the second trench 315t1 so as to be in contact with the second signal line 245i-1. The shield pattern 325-3 may be electrically connected to the ground line via the second signal line 245i-1. When the static electricity is introduced from the outside out of the display panel into the display panel, the shield pattern 325-3 may quickly discharge the introduced static electricity to the outside via the ground line. Accordingly, the shield pattern 325-3 may prevent the light-emitting element or the circuit elements including the transistor inside the display panel from being damaged by the static electricity.

The passivation layer 335 including the inorganic insulating material may be disposed on the touch electrode 325, the touch insulating layer 315, and a partial area of the shield pattern 325-3. The passivation layer 335 may be disposed on the surface of the touch insulating layer 315 exposed through the first trench 315t among the plurality of trenches. The passivation layer 335 may be disposed on the surface of the shield pattern 325-3 exposed through the second trench 315t1 among the plurality of trenches.

The plurality of lens dams 500 may be disposed in the first bezel area BZA1 and the second bezel area BZA2. The plurality of lens dams 500 may include the first lens dam 510, the second lens dam 520, and the third lens dam 530.

Referring to FIGS. 12 and 15 together with each other, the first lens dam 510 may be disposed to overlap the first encapsulation dam 410 in the vertical direction. The first lens dam 510 may include the first head portion 511 and the first pillar portion 513. The first pillar portion 513 of the first lens dam 510 may fill the first trench 315t. The first head portion 511 of the first lens dam 510 may be integrally formed with the first pillar portion 513. The first center line C1 of the first width 510w of the first head portion 511 of the first lens dam 510 may coincide with the second center line C2 of the second width 410w of the first encapsulation dam 410.

The second lens dam 520 may be disposed outwardly of the first lens dam 510. The third lens dam 530 may be disposed outwardly of the second lens dam 520. The third lens dam 530 may include the first pattern portion 530aand the second pattern portion 530b. The second pattern portion 530b of the third lens dam 530 may be an extension pattern extending from one side surface of the first pattern portion 530a outwardly. The second pattern portion 530bmay fill the second trench 315t1 and may extend toward the outer edge (or the side end) of the substrate 205. For example, the second pattern portion 530bmay extend along and on the inclined surface 315iof the touch insulating layer 315.

The polarization layer 360 may be disposed on the lens protection layer 350. The polarizing layer 360 may extend on the side end of the touch insulating layer 315 while contacting the upper surface of each of the first lens dam 510, the second lens dam 520, and the third lens dam 530.

In the display apparatus according to still another embodiment of the present disclosure, the trench and the shield pattern may prevent the penetration of moisture into the inside of the display panel and prevent the static electricity from being introduced into the inside of the display panel.

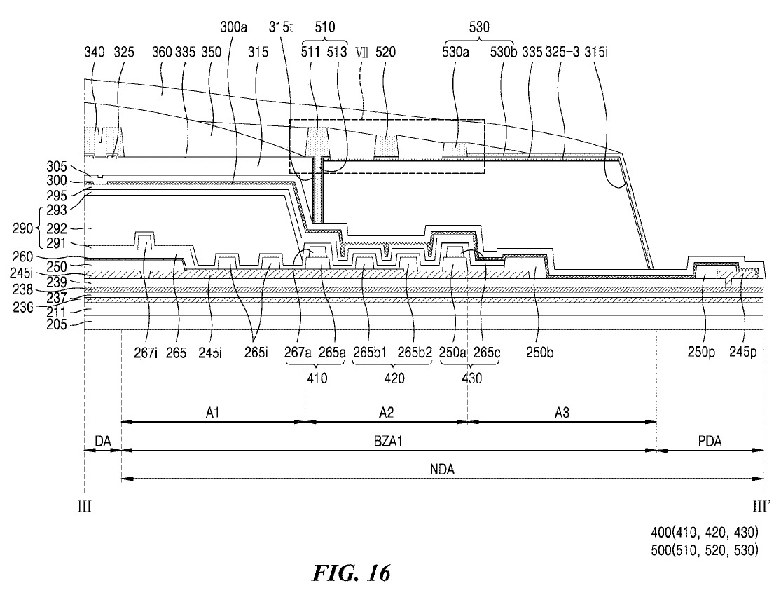

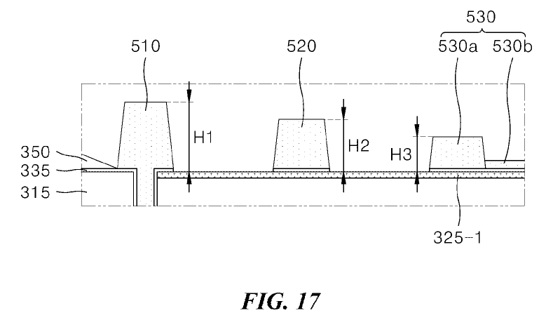

FIGS. 16 and 17 are diagrams illustrating a display apparatus according to still yet another embodiment of the present disclosure. FIG. 17 is an enlarged view of an area VII of FIG. 16. Since FIGS. 16 and 17 include the same components as those in FIG. 15 except for the lens dams, redundant descriptions thereof will be omitted or briefly set forth, and differences therebetween will be described. Like reference numerals may denote like elements.

Referring to FIGS. 16 and 17, the plurality of lens dams 500 may be disposed on the passivation layer 335. The plurality of lens dams 500 may include the first lens dam 510 overlapping the first trench 315t, the second lens dam 520, and the third lens dam 530. Each of the plurality of lens dams 500 may be made of the same material as that of the lens 340 of the display area DA and be formed in the same process as the process for forming the lens 340 of the display area DA.

At least one of the plurality of lens dams 500 may be disposed in the second area A2 of the first bezel area BZA1 and the second bezel area BZA2 in which the first, second and third encapsulation dams 410, 420, and 430 are disposed. For example, the first lens dam 510 may be disposed to overlap the underlying first encapsulation dam 410 in the vertical direction. For example, as illustrated in FIG. 12, the first center line C1 of the first width 510w of the first head portion 511 of the first lens dam 510 may coincide with the second center line C2 of the second width 410w of the first encapsulation dam 410 positioned thereunder.

The first, second and third lens dams 510, 520, and 530 may be constructed to have different heights. For example, the first height H1 of the first head portion 511 of the first lens dam 510 may be the largest. Each of the second height H2 of the second lens dam 520 and the third height H3 of the third lens dam 530 may be smaller than the first height H1 of the first head portion 511 of the first lens dam 510.

Each of the first, second and third heights H1, H2, and H3 of the first, second and third lens dams 510, 520, and 530 according to still yet another embodiment of the present disclosure may be greater than the width in the direction from the lens to the side end of the substrate of the bottom surface of each of the first, second and third lens dams 510, 520, and 530. The first lens dam 510, the second lens dam 520, and the third lens dam 530 may be arranged in a stepwise manner whose the vertical levels of the upper surfaces thereof are sequentially lowered as the first lens dam 510, the second lens dam 520, and the third lens dam 530 are sequentially arranged in a direction toward the side end of the substrate 205. The second lens dam 520 may be disposed between the first lens dam 510 and the third lens dam 530.

The polarizing layer 360 may continuously extend across the first area A1 to the third area A3 and be attached to the first area A1 to the third area A3. The polarizing layer 360 may be in contact with the first, second and third lens dams 520, 520, and 530 arranged in the stepwise manner. Accordingly, the vertical level of the upper surface of the polarizing layer 360 may be gradually lowered as the polarizing layer 360 extends toward the third area A3. As a result, the polarizing layer 360 may be closely attached to the second pattern portion 530b of the third lens dam 530 disposed in the edge of the third area A3 and may not lift off.

The display apparatus according to various aspects and embodiments of the present disclosure may be described as follows.

One aspect of the present disclosure provides a display apparatus comprising: a substrate including a display area and a non-display area disposed outside the display area; a bezel area disposed in the non-display area in which a plurality of first structures are disposed; an encapsulation portion disposed on the plurality of first structures; a touch sensing unit disposed on the encapsulation portion and including a touch sensor and a touch insulating layer; a lens disposed on the touch sensing unit; a lens protection layer disposed on the lens; a plurality of second structures disposed on the touch insulating layer to be spaced apart from the lens, wherein at least one of the plurality of second structures overlaps the plurality of first structures; and a shield pattern disposed on the touch insulating layer in the bezel area.

According to some embodiments of the present disclosure, the bezel area includes a first area adjacent to the display area, a third area adjacent to a side end of the substrate, and a second area between the first area and the third area in which the plurality of first structures are disposed; and the shield pattern is disposed in the second area and the third area.

According to some embodiments of the present disclosure, the display apparatus further comprises a first trench penetrating the touch insulating layer in the second area.

According to some embodiments of the present disclosure, the shield pattern covers a portion of an upper surface of the touch insulating layer between adjacent ones of the plurality of second structures.

According to some embodiments of the present disclosure, the display apparatus further comprises a signal line disposed in in the bezel area, a second trench penetrating the touch insulating layer in the third area and exposing a portion of a surface of the signal line, wherein the shield pattern is disposed on a side wall and a bottom surface of the second trench and is in contact with the signal line.

According to some embodiments of the present disclosure, one side end of the touch insulating layer is disposed in the third area and has an inclined surface, and the shield pattern is disposed on the inclined surface of the touch insulating layer.

According to some embodiments of the present disclosure, one second structure among the plurality of second structures includes: a first pillar portion filling the first trench; and a first head portion disposed on the first pillar portion.

According to some embodiments of the present disclosure, the plurality of first structures include: a first encapsulation dam disposed in the second area and in the boundary area between the first area and the second area; a third encapsulation dam disposed in the second area and in a boundary area between the second area and the third area; and a second encapsulation dam disposed between the first encapsulation dam and the third encapsulation dam, wherein the first encapsulation dam is disposed to overlap one of the plurality of second structures in the vertical direction.

According to some embodiments of the present disclosure, the plurality of second structures includes: a first lens dam disposed in the second area; a second lens dam disposed outwardly of the first lens dam; and a third lens dam disposed outwardly of the second lens dam, wherein the first lens dam fills the first trench and overlaps the first encapsulation dam in the vertical direction.

According to some embodiments of the present disclosure, the first lens dam includes a first pillar portion filling the first trench and a first head portion disposed on the first pillar portion, and a bottom surface of the first head portion has a first width, wherein a bottom surface of the first encapsulation dam has a second width, and wherein a first center line passing through a center portion of the first width of the first lens dam and a second center line passing through a center of the second width of the first encapsulation dam are aligned to coincide with each other.

According to some embodiments of the present disclosure, a height of the first head portion of the first lens dam is smaller than the first width, and each of the second lens dam and the third lens dam is configured to have the first width and the height.

According to some embodiments of the present disclosure, an upper surface of the first lens dam is positioned at a vertical level higher than a vertical level of an upper surface of the second lens dam or an upper surface of the third lens dam.

According to some embodiments of the present disclosure, the third lens dam includes a first pattern portion and a second pattern portion extending from one side surface of the first pattern portion outwardly.

According to some embodiments of the present disclosure, a side end of the touch insulating layer is disposed in the third area, and the second pattern portion of the third lens dam covers the side end of the touch insulating layer.

According to some embodiments of the present disclosure, the plurality of second structure and the lens are made of the same material and are formed in the same process.

According to some embodiments of the present disclosure, one side end of the touch insulating layer is disposed in the third area, and the side end of the touch insulating layer is aligned with a side end of the shield pattern.

According to some embodiments of the present disclosure, an upper surface of the second pattern portion is positioned at a lower vertical level than a vertical level of an upper surface of the first pattern portion.

Another aspect of the present disclosure provides a display apparatus comprising: a substrate including a display area and a non-display area disposed outside the display area; a bezel area disposed in the non-display area in which a plurality of encapsulation dams are disposed on the substrate; an encapsulation portion disposed on the plurality of encapsulation dams; a touch sensing unit disposed on the encapsulation portion and including a touch sensor and a touch insulating layer; a lens disposed on the touch sensing unit; a lens protection layer disposed on the lens; and a plurality of lens dams disposed on the touch insulating layer to be spaced apart from the lens, wherein at least one of the plurality of lens dams overlaps the plurality of encapsulation dams, and a first trench is defined in the touch insulating layer in the bezel area.

According to some embodiments of the present disclosure, the first trench has a ring shape surrounding an outer periphery of the display area in the plan view such that the touch insulating layer is divided into two portions around the first trench interposed therebetween.

According to some embodiments of the present disclosure, the first trench is disposed to overlap one of the plurality of encapsulation dams in the vertical direction and filled with one of the plurality of lens dams.

According to some embodiments of the present disclosure, a surface of the touch insulating layer exposed through the first trench is covered with a passivation layer of the touch sensing unit.

According to some embodiments of the present disclosure, the display apparatus further comprises a shield pattern disposed on an outer portion of the touch insulating layer adjacent to a side end of the substrate.

According to some embodiments of the present disclosure, the display apparatus further comprises a signal line disposed in the bezel area, wherein a second trench is defined in a portion of the touch insulating layer adjacent to the side end of the substrate to expose a portion of an upper surface of the signal line, and the shield pattern fills the second trench to be in contact with the signal line.

According to some embodiments of the present disclosure, the shield pattern covers a portion of an upper surface of the touch insulating layer disposed between adjacent ones of the plurality of lens dams.

According to some embodiments of the present disclosure, the shield pattern covers an inclined surface of a side end of the touch insulating layer.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A display apparatus comprising:
a substrate including a display area and a non-display area disposed outside the display area;
a bezel area disposed in the non-display area in which a plurality of first structures are disposed on the substrate;
an encapsulation portion disposed on the plurality of first structures;
a touch sensing unit disposed on the encapsulation portion and including a touch sensor and a touch insulating layer;
a lens disposed on the touch sensing unit;
a lens protection layer disposed on the lens;
a plurality of second structures disposed on the touch insulating layer to be spaced apart from the lens, wherein at least one of the plurality of second structures overlaps the plurality of first structures; and
a shield pattern disposed on the touch insulating layer in the bezel area.

2. The display apparatus of claim 1, wherein the bezel area includes a first area adjacent to the display area, a third area adjacent to a side end of the substrate, and a second area between the first area and the third area in which the plurality of first structures are disposed; and
wherein the shield pattern is disposed in the second area and the third area.

3. The display apparatus of claim 2, further comprising a first trench penetrating the touch insulating layer in the second area.

4. The display apparatus of claim 1, wherein the shield pattern covers a portion of an upper surface of the touch insulating layer between adjacent ones of the plurality of second structures.

5. The display apparatus of claim 3, further comprising a signal line disposed in the bezel area,
a second trench penetrating the touch insulating layer in the third area and exposing a portion of a surface of the signal line,
wherein the shield pattern is disposed on a side wall and a bottom surface of the second trench and is in contact with the signal line.

6. The display apparatus of claim 2, wherein one side end of the touch insulating layer is disposed in the third area and has an inclined surface, and
wherein the shield pattern is disposed on the inclined surface of the touch insulating layer.

7. The display apparatus of claim 3, wherein one second structure among the plurality of second structures includes:
a first pillar portion filling the first trench; and
a first head portion disposed on the first pillar portion.

8. The display apparatus of claim 3, wherein the plurality of first structures include:
a first encapsulation dam disposed in the second area and in a boundary area between the first area and the second area;
a third encapsulation dam disposed in the second area and in a boundary area between the second area and the third area; and
a second encapsulation dam disposed between the first encapsulation dam and the third encapsulation dam,
wherein the first encapsulation dam is disposed to overlap one of the plurality of second structures in a vertical direction.

9. The display apparatus of claim 8, wherein the plurality of second structures includes:
a first lens dam disposed in the second area;
a second lens dam disposed outwardly of the first lens dam; and
a third lens dam disposed outwardly of the second lens dam,
wherein the first lens dam fills the first trench and overlaps the first encapsulation dam in the vertical direction.

10. The display apparatus of claim 9, wherein the first lens dam includes a first pillar portion filling the first trench and a first head portion disposed on the first pillar portion, and a bottom surface of the first head portion has a first width,
wherein a bottom surface of the first encapsulation dam has a second width, and
wherein a first center line passing through a center portion of the first width of the first lens dam and a second center line passing through a center of the second width of the first encapsulation dam are aligned to coincide with each other.

11. The display apparatus of claim 10, wherein a height of the first head portion of the first lens dam is smaller than the first width, and each of the second lens dam and the third lens dam is configured to have the first width and the height.

12. The display apparatus of claim 9, wherein an upper surface of the first lens dam is disposed at a position higher than an upper surface of the second lens dam or an upper surface of the third lens dam.

13. The display apparatus of claim 9, wherein the third lens dam includes a first pattern portion and a second pattern portion extending from one side surface of the first pattern portion.

14. The display apparatus of claim 13, wherein an end portion of the touch insulating layer is disposed in the third area, and
wherein the second pattern portion of the third lens dam covers the end portion of the touch insulating layer.

15. The display apparatus of claim 1, wherein the plurality of second structures and the lens are made of the same material and are formed in the same process.

16. The display apparatus of claim 2, wherein one side end of the touch insulating layer is disposed in the third area, and
wherein the side end of the touch insulating layer is aligned with a side end of the shield pattern.

17. The display apparatus of claim 13, wherein an upper surface of the second pattern portion is positioned at a lower vertical level than a vertical level of an upper surface of the first pattern portion.

18. A display apparatus comprising:
a substrate including a display area and a non-display area disposed outside the display area;
a bezel area disposed in the non-display area in which a plurality of encapsulation dams are disposed on the substrate;
an encapsulation portion disposed on the plurality of encapsulation dams;
a touch sensing unit disposed on the encapsulation portion and including a touch sensor and a touch insulating layer;
a lens disposed on the touch sensing unit;
a lens protection layer disposed on the lens; and
a plurality of lens dams disposed on the touch insulating layer to be spaced apart from the lens, wherein at least one of the plurality of lens dams overlaps the plurality of encapsulation dams, and
wherein a first trench is defined in the touch insulating layer in the bezel area.

19. The display apparatus of claim 18, wherein the first trench has a ring shape surrounding an outer periphery of the display area in a plan view such that the touch insulating layer is divided into two portions around the first trench interposed therebetween.

20. The display apparatus of claim 18, wherein the first trench is disposed to overlap one of the plurality of encapsulation dams in a vertical direction and filled with one of the plurality of lens dams.

21. The display apparatus of claim 18, wherein a surface of the touch insulating layer exposed through the first trench is covered with a passivation layer of the touch sensing unit.

22. The display apparatus of claim 19, further comprising a shield pattern disposed on an outer portion of the touch insulating layer adjacent to a side end of the substrate.

23. The display apparatus of claim 22, further comprising a signal line disposed in the bezel area, wherein a second trench is defined in a portion of the touch insulating layer adjacent to the side end of the substrate to expose a portion of an upper surface of the signal line, and the shield pattern fills the second trench to be in contact with the signal line.

24. The display apparatus of claim 22, wherein the shield pattern covers a portion of an upper surface of the touch insulating layer disposed between adjacent ones of the plurality of lens dams.

25. The display apparatus of claim 24, wherein the shield pattern covers an inclined surface of a side end of the touch insulating layer.
